(19) United States
(12) Patent Application Publication
(10) Pub. No.: US 2024/0114739 A1
(43) Pub. Date: Apr. 4, 2024

(54) DISPLAY APPARATUS

(71) Applicant: Samsung Display Co., Ltd., Yongin-si (KR)

(72) Inventors: SEUNG-LYONG BOK, Yongin-si (KR); Chang Sik KIM, Yongin-si (KR); JUNGJIN YANG, Yongin-si (KR); HYEIN JEONG, Yongin-si (KR)

(21) Appl. No.: 18/368,498

(22) Filed: Sep. 14, 2023

(30) Foreign Application Priority Data
Sep. 29, 2022 (KR) 10-2022-0123996

(51) Int. Cl. H10K 59/35; H10K 59/122

(52) U.S. Cl. CPC H10K 59/352; H10K 59/122; H10K 59/351

(57) ABSTRACT

A display apparatus includes a first area and a second area, a pixel defining layer having a first opening in the first area with a first area size, and a second opening in the second area with a second area size, a first light emitting unit having an emission area size corresponding to the first area size and emitting first color light, a second light emitting unit having an emission area size corresponding to the second area size and emitting the first color light, a first pixel circuit in the second area and connected to the first light emitting unit, a second pixel circuit in the second area and connected to the second light emitting unit, and an electronic module in the first area and overlapping the first opening. An opening rate of the first light emitting unit is smaller than that of the second light emitting unit.

### CROSS-REFERENCE TO RELATED APPLICATIONS

The present application claims priority to and the benefit of Korean Patent Application No. 10-2022-0123996 filed on Sep. 29, 2022, in the Korean Intellectual Property Office, the entire disclosure of which is incorporated herein by reference.

### BACKGROUND

### 1. Field

Aspects of an embodiment of the present disclosure described herein relate to a display apparatus.

### 2. Description of the Related Art

An electronic device may include various electronic components such as a display panel, an electronic module, and the like. The electronic module may include a camera, an infrared sensor, a proximity sensor, or the like. The electronic module may be located under the display panel. Transmittance of a partial area of the display panel may be higher than transmittance of another area of the display panel. Through the area having high transmittance, the electronic module may receive an optical signal or may output an optical signal.

The above information disclosed in this Background section is only for enhancement of understanding of the background and therefore the information discussed in this Background section does not necessarily constitute prior art.

### SUMMARY

Aspects of an embodiment of the present disclosure described herein relate to a display apparatus, and for example, relate to a display apparatus including an electronic module.

Aspects of an embodiment of the present disclosure include a display panel including an area having relatively high transmittance that is capable of transmitting an optical signal and a display apparatus including the same.

According to an embodiment, a display apparatus includes a base substrate divided into a first area and a second area adjacent to the first area, a pixel defining layer, which is on the base substrate and in which a first opening in the first area and having a first area size, and a second opening in the second area and having a second area size greater than the first area size are defined, a first light emitting unit having an emission area size corresponding to the first area size and emitting first color light, a second light emitting unit having an emission area size corresponding to the second area size and emitting the first color light, a first pixel circuit in the second area and connected to the first light emitting unit, a second pixel circuit in the second area and connected to the second light emitting unit, and an electronic module in the first area and overlapping the first opening. According to an embodiment, the first light emitting unit includes a first charge generation layer. According to an embodiment, an opening rate of the first light emitting unit is smaller than an opening rate of the second light emitting unit.

According to an embodiment, the first color light may be red.

According to an embodiment, the first color light may be blue.

According to an embodiment, the first light emitting unit may have an opening rate of 12% or less.

According to an embodiment, the first color light may be green.

According to an embodiment, the first light emitting unit may have an opening rate of 8% or less.

According to an embodiment, the first light emitting unit may include a plurality of light emitting layers, and the second light emitting unit may include a single light emitting layer.

According to an embodiment, the display apparatus may further include a third light emitting unit in the first area and emitting second color light different from the first color light. According to an embodiment, the first light emitting unit may include a plurality of light emitting layers. According to an embodiment, the third light emitting unit may include a single light emitting layer.

According to an embodiment, the first color light may be white.

According to an embodiment, the electronic module may include a camera, an ultrasonic sensor, or an optical sensor.

According to an embodiment, the first area size may be about ½ to about ⅓ of the second area size.

According to an embodiment, a display apparatus includes a base substrate divided into a first area and a second area adjacent to the first area, a first light emitting unit in the first area and including a first anode having a first area size, a first light emitting layer, a second light emitting layer, and a first cathode, a second light emitting unit in the second area and including a second anode having a second area size greater than the first area size, a third light emitting layer, and a second cathode, a third light emitting unit in the first area and including a third anode, a fourth light emitting layer, and a third cathode, and an electronic module in the first area and overlapping a first opening. According to an embodiment, the first light emitting unit and the second light emitting unit emit first color light. According to an embodiment, the third light emitting unit emits second color light different from the first color light. According to an embodiment, the first area size is ½ or less of the second area size.

According to an embodiment, the first light emitting unit may have an opening rate of 12% or less.

According to an embodiment, the first color light may be blue. According to an embodiment, the third light emitting unit may include a single light emitting layer.

According to an embodiment, the third light emitting unit may further include a fourth light emitting layer.

According to an embodiment, the second color light may be red, and the third light emitting unit may have an opening rate of 5% or less.

According to an embodiment, the second color light may be green, and the third light emitting unit may have an opening rate of 8% or less.

According to an embodiment, the second light emitting unit may include a single light emitting layer.

According to an embodiment, the display apparatus includes a first opening exposing at least part of the first anode, a second opening exposing at least part of the second anode, and a pixel defining layer exposing at least part of the third anode. According to an embodiment, a fourth opening in the first area and spaced from the first opening and the second opening is defined on the pixel defining layer. According to an embodiment, a light emitting layer is not in the fourth opening.

According to an embodiment, a plurality of first openings included in the first opening, a plurality of second openings included in the second opening, and a plurality of fourth openings included in the fourth opening may be provided in the first area. According to an embodiment, the plurality of first openings, the plurality of second openings, and the plurality of fourth openings may be alternately arranged.

### BRIEF DESCRIPTION OF THE DRAWINGS

The above and other characteristics and features of the present disclosure will become apparent by describing in more detail embodiments thereof with reference to the accompanying drawings.

FIG. 1 is a cross-sectional view of an electronic device, according to an embodiment of the present disclosure.

FIG. 2A is an exploded perspective view of an electronic device, according to an embodiment of the present disclosure.

FIG. 2B is a block diagram of an electronic device, according to an embodiment of the present disclosure.

FIG. 3 is a cross-sectional view of a display module, according to an embodiment of the present disclosure.

FIG. 4 is an equivalent circuit diagram of a pixel, according to an embodiment of the present disclosure.

FIG. 5A is a plan view of a display panel, according to an embodiment of the present disclosure.

FIG. 5B is an enlarged plan view of a portion of FIG. 5A.

FIG. 5C is an enlarged plan view of a portion of FIG. 5B.

FIG. 5D is an enlarged plan view of another portion of FIG. 5B.

FIG. 5E is a plan view of a display panel, according to an embodiment of the present disclosure.

FIG. 6A is a cross-sectional view corresponding to a first area and a second area of a display device, according to an embodiment of the present disclosure.

FIG. 6B is a cross-sectional view corresponding to a third area of a display device, according to an embodiment of the present disclosure.

FIGS. 7A to 7D are graphs showing a lifetime of a light emitting element, according to an embodiment of the present disclosure.

FIG. 8 is a cross-sectional view of a first light emitting element, according to an embodiment of the present disclosure.

FIGS. 9 and 10 are cross-sectional views of a display panel, according to an embodiment of the present disclosure.

FIGS. 11A to 11C are plan views schematically illustrating a portion of a display panel, according to an embodiment of the present disclosure.

### DETAILED DESCRIPTION

In the specification, the expression that a first component (or region, layer, part, etc.) is “on”, “connected with”, or “coupled with” a second component means that the first component is directly on, connected with, or coupled with the second component or means that a third component is interposed therebetween.

Like reference numerals refer to like components. Also, in drawings, the thickness, ratio, and dimension of components are exaggerated for effectiveness of description of technical contents.

The term “and/or” includes one or more combinations of the associated listed items.

Although the terms “first”, “second”, etc. may be used to describe various components, the components should not be construed as being limited by the terms. The terms are only used to distinguish one component from another component. For example, without departing from the scope and spirit of the present disclosure, a first component may be referred to as a second component, and similarly, the second component may be referred to as the first component. The articles “a,” “an,” and “the” are singular in that they have a single referent, but the use of the singular form in the specification should not preclude the presence of more than one referent.

Also, the terms “under”, “beneath”, “on”, “above”, etc. are used to describe a relationship between components illustrated in a drawing. The terms are relative and are described with reference to a direction indicated in the drawing.

Unless otherwise defined, all terms (including technical terms and scientific terms) used in this specification have the same meaning as commonly understood by those skilled in the art to which the present disclosure belongs. Furthermore, terms such as terms defined in commonly used dictionaries should be interpreted as having a meaning consistent with the meaning in the context of the related technology, and may be explicitly defined herein unless interpreted in ideal or overly formal meanings.

It will be understood that the terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, or components or a combination thereof.

Hereinafter, aspects of an embodiment of the present disclosure will be described with reference to accompanying drawings.

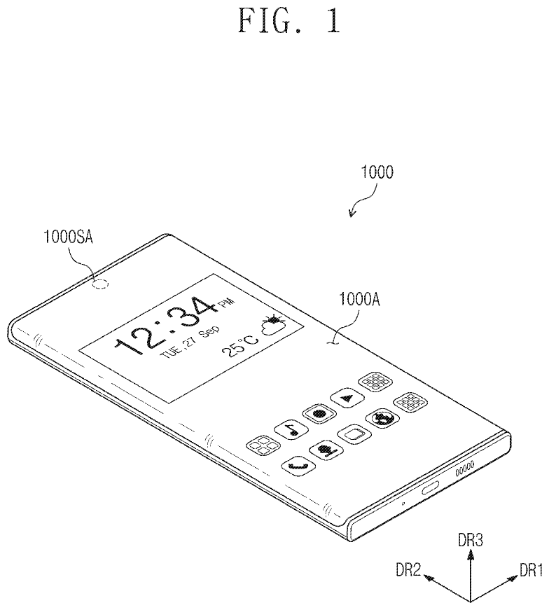

FIG. 1 is a perspective view of an electronic device 1000, according to an embodiment of the present disclosure.

Referring to FIG. 1, according to an embodiment, the electronic device 1000 is illustrated as a mobile phone. However, embodiments according to the present disclosure are not limited thereto. For example, the electronic device 1000 may be any other suitable electronic device having display capabilities, such as a tablet PC, a monitor, a television, a car navigation system, a game console, or a wearable device.

The electronic device 1000 may display images through a display area 1000A. The display area 1000A may include a plane defined by a first direction DR1 and a second direction DR2. The display area 1000A may further include curved surfaces, each of which is bent from at least two sides of the plane. However, the shape of the display area 1000A is not limited thereto. For example, the display area 1000A may include only the plane. The display area 1000A may further include at least two or more (e.g., four) curved surfaces of the plane that are respectively bent from four side surfaces or edges. Additionally, according to an embodiment, the display area 1000A may have a polygonal or irregular shape in a plan view (e.g., a view perpendicular or normal with respect to a plane parallel to a display surface of the electronic device 1000).

A part of the display area 1000A may be defined as a sensing area 1000SA. The single sensing area 1000SA is shown in FIG. 1, but the number of the sensing areas 1000SA is not limited thereto. The sensing area 1000SA may be a part of the display area 1000A. However, the sensing area 1000SA may have higher light transmittance than other areas of the display area 1000A outside of the sensing area 1000SA. Accordingly, the sensing area 1000SA may be an area, through which light passes, while images are displayed. Light (hereinafter, referred to as a “light signal”) referred to herein includes visible light. However, the light is not limited thereto. As long as the light such as ultraviolet light or infrared light corresponds to a detectable signal, the light may have various types, and is not limited to an embodiment.

The electronic device 1000 may include an electronic optical module located in an area overlapping the sensing area 1000SA. The electronic optical module may receive an optical signal provided from the outside through the sensing area 1000SA or may output an optical signal through the sensing area 1000SA. For example, the electronic optical module may be a camera module, a sensor, which measures a distance between an object and a mobile phone, such as a proximity sensor, a sensor that recognizes a part (e.g., a fingerprint, an iris, or a face) of a user's body, or a small lamp that outputs light, but is not particularly limited thereto.

A thickness direction of the electronic device 1000 may be a third direction DR3 that is a normal or perpendicular direction relative to a plane that is parallel to the display area 1000A (or the majority of the display area 1000A, excluding, for example, curved surfaces). Accordingly, front surfaces (or upper surfaces) and back surfaces (or lower surfaces) of members constituting the electronic device 1000 may be defined based on the third direction DR3.

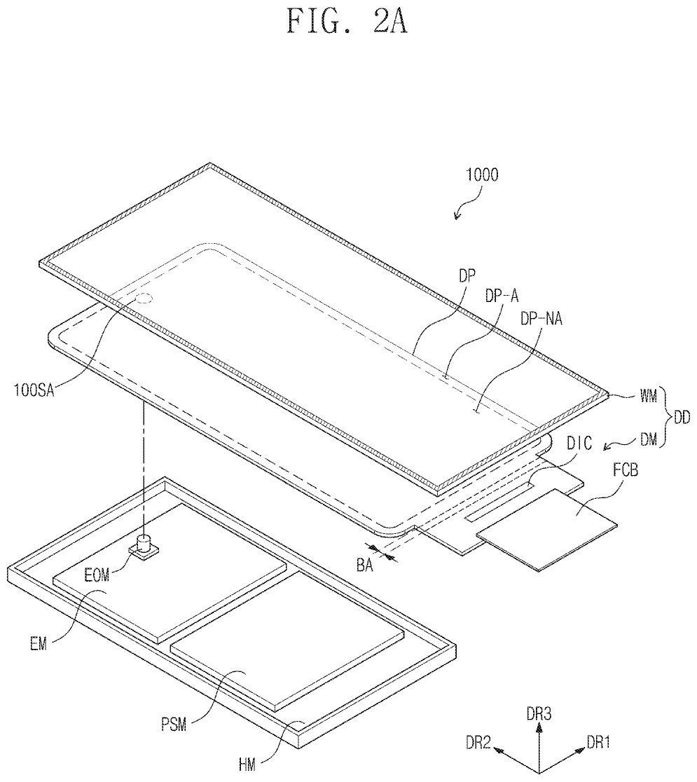

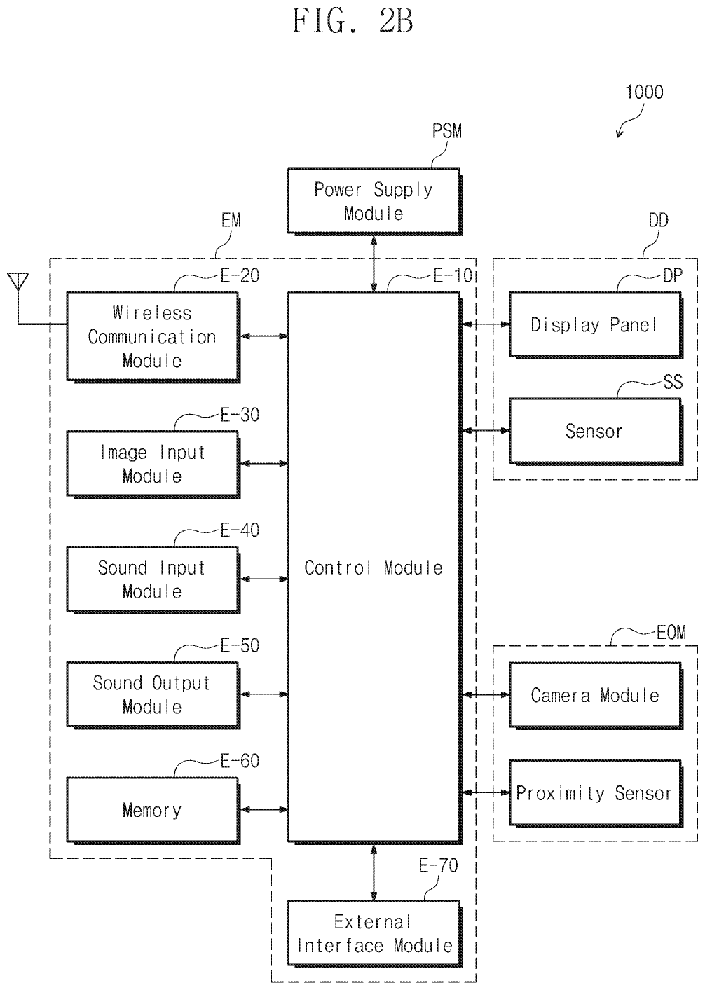

FIG. 2A is an exploded perspective view of the electronic device 1000, according to an embodiment of the present disclosure. FIG. 2B is a block diagram of the electronic device 1000, according to an embodiment of the present disclosure.

As illustrated in FIGS. 2A and 2B, the electronic device 1000 may include a display device DD, an electronic module EM, an electronic optical module EOM, a power supply module PSM, and housing HM. The electronic device 1000 may further include additional configurations not shown.

The display device DD generates an image and detects at least one external input. The display device DD includes a window WM and a display module DM.

The window WM provides a front surface of the electronic device 1000. The window WM may include a glass film or a synthetic resin film as a base film. The window WM may further include an anti-reflection layer or an anti-fingerprint layer. The window WM may further include a bezel pattern overlapping a peripheral area DP-NA of a display panel DP. The window WM and the display module DM may be coupled to each other through an adhesive layer.

The display module DM may include the at least one display panel DP. In FIG. 2A, only the display panel DP is shown in a stacked structure of the display module DM. However, the display module DM may further include a plurality of configurations located on the display panel DP substantially. A detailed description of the stacked structure of the display module DM will be described in more detail later.

The display panel DP may include a display area DP-A and the peripheral area DP-NA. The display area DP-A may correspond to the display area 1000A shown in FIG. 1. A pixel PX is located in the display area DP-A. In more detail, light emitting elements may be positioned in the display area DP-A, and a light emitting element may not be positioned in the peripheral area DP-NA.

The display panel DP may include a sensing area 100SA corresponding to the sensing area 1000SA of FIG. 1. The sensing area 100SA may have lower resolution than other areas of the display area DP-A. A detailed description of the sensing area 100SA will be described later.

As shown in FIG. 2A, a driver chip DIC may be positioned on the peripheral area DP-NA of the display panel DP. A flexible printed circuit board FCB may be coupled to the peripheral area DP-NA of the display panel DP. The flexible printed circuit board FCB may be connected to a main circuit board. The main circuit board may be one electronic component constituting the electronic module EM. A bending area BA of the peripheral area DP-NA may be bent such that the flexible printed circuit board FCB is located under the display area DP-A.

The driver chip DIC may include driving elements (e.g., data driving circuits) for driving the pixel PX. FIG. 2A illustrates a structure in which the driver chip DIC is mounted on the display panel DP, but the present disclosure is not limited thereto. For example, the driver chip DIC may be mounted on the flexible printed circuit board FCB.

The electronic module EM and the power supply module PSM may be accommodated in the housing HM. The housing HM is coupled to the display device DD (especially the window WM) to accommodate the other modules.

As shown in FIG. 2B, the display device DD may include the display panel DP and a sensor SS. The sensor SS may include one or more of an input sensor, an antenna sensor, and a fingerprint sensor.

The electronic module EM may include a control module E-10, a wireless communication module E-20, an image input module E-30, a sound input module E-40, a sound output module E-50, a memory E-60, and an external interface module E-70. The electronic module EM may include a main circuit board, and the modules may be mounted on the main circuit board or may be electrically connected to the main circuit board through a flexible circuit board. The electronic module EM is electrically connected to the power supply module PSM.

The control module E-10 controls overall operations of the electronic device 1000. For example, the control module E-10 activates or deactivates the display device DD in response to a user input. The control module E-10 may control the image input module E-30, the sound input module E-40, the sound output module E-50, or the like in response to a user input. The control module E-10 may include at least one microprocessor.

The wireless communication module E-20 may transmit/receive wireless signals with another terminal by using, for example, a wireless communication channel or protocol, such as Bluetooth™ or Wi-Fi. The wireless communication module E-20 may transmit/receive voice signals by using general communication lines. The wireless communication module E-20 may include a plurality of antenna modules.

The image input module E-30 converts an image signal into image data capable of being displayed on the display device DD by processing the image signal. In a recording mode, a speech recognition mode, or the like, the sound input module E-40 receives an external sound signal from a microphone and then converts the external sound signal into electrical voice data. The sound output module E-50 converts sound data received from the wireless communication module E-20 or sound data stored in the memory E-60 and then outputs the converted data to the outside.

The external interface module E-70 operates as an interface that connects to an external charger, a wired/wireless data port, a card socket (e.g., a memory card, a SIM/UIM card, or the like), or the like.

The power supply module PSM supplies power necessary for overall operations of the electronic device 1000. The power supply module PSM may include a general battery device.

The electronic optical module EOM may be an electronic component that outputs or receives an optical signal. The electronic optical module EOM may include a camera module and/or a proximity sensor. The camera module captures an external image through the sensing area 1000SA.

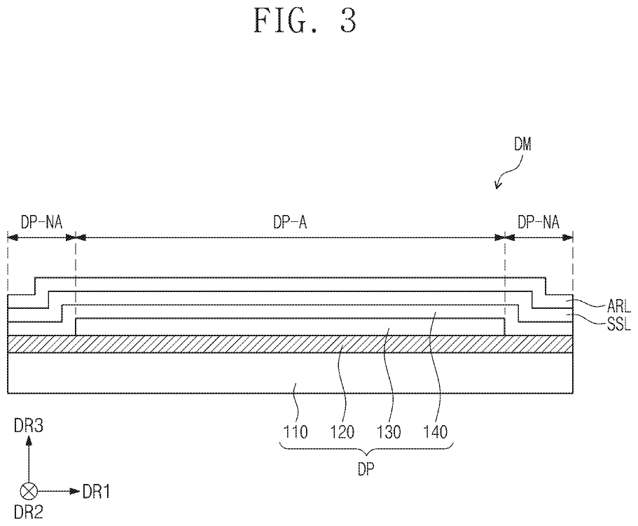

FIG. 3 is a cross-sectional view of the display module DM, according to an embodiment of the present disclosure.

Referring to FIG. 3, the display device DD may include the display panel DP, a sensor layer SSL, and an anti-reflection layer ARL. The display panel DP may be a configuration that substantially generates an image. The display panel DP may be a light emitting display panel. For example, the display panel DP may be an organic light emitting display panel, an inorganic light emitting display panel, a micro-LED display panel, or a nano-LED display panel. The display panel DP may also be referred to as a “display layer”.

The display panel DP may include a base layer 110, a circuit layer 120, a light emitting element layer 130, and an encapsulation layer 140.

The base layer 110 may be a member that provides a base surface on which the circuit layer 120 is located. The base layer 110 may be a rigid substrate, or a flexible substrate capable of bending, folding, rolling, or the like. The base layer 110 may be a glass substrate, a metal substrate, a polymer substrate, or the like. However, embodiments of the present disclosure are not limited thereto, but the base layer 110 may be an inorganic layer, an organic layer, or a composite material layer.

The base layer 110 may have a multi-layer structure. For example, the base layer 110 may include a first synthetic resin layer, an inorganic layer having a multi-layer structure or a single layer structure, and a second synthetic resin layer located on the inorganic layer having a multi-layer structure or a single layer structure. Each of the first and second synthetic resin layers may include a polyimide-based resin, and is not particularly limited.

The base layer 110 may include the display area DP-A and the peripheral area DP-NA. In the base layer 110, an area defined in the display panel DP is equally defined.

The circuit layer 120 may be located on the base layer 110. The circuit layer 120 may include an insulating layer, a semiconductor pattern, a conductive pattern, and a signal line.

The light emitting element layer 130 may be located on the circuit layer 120. The light emitting element layer 130 may include a light emitting element. For example, the light emitting element may include an organic light emitting material, an inorganic light emitting material, an organic-inorganic light emitting material, a quantum dot, a quantum rod, a micro-LED, or a nano-LED.

The encapsulation layer 140 may be located on the light emitting element layer 130. The encapsulation layer 140 may protect the light emitting element layer 130 from foreign substances such as moisture, oxygen, and dust particles. The encapsulation layer 140 may include at least one inorganic layer. The encapsulation layer 140 may include a stacked structure of an inorganic layer/organic layer/inorganic layer.

The sensor layer SSL may be located on the display panel DP. The sensor layer SSL may include one or more of an input sensor, an antenna sensor, and a fingerprint sensor. The sensor layer SSL may be formed on the display panel DP through sequential processes. In this case, the sensor layer SSL may be directly located on the display panel DP. Here, “being directly located” may mean that a third component is not interposed between the sensor layer SSL and the display panel DP. That is, an adhesive layer may not be interposed between the sensor layer SSL and the display panel DP.

The anti-reflection layer ARL may be directly located on the sensor layer SSL. The anti-reflection layer ARL may reduce the reflectance of external light incident from the outside of the display device DD. The anti-reflection layer ARL may be formed on the sensor layer SSL through sequential processes. The anti-reflection layer ARL may include color filters. The color filters may have a given arrangement. For example, the color filters may be arranged in consideration of emission colors of pixels included in the display panel DP. Besides, the anti-reflection layer ARL may further include a black matrix adjacent to the color filters. Further detailed description of the anti-reflection layer ARL will be described later.

According to an embodiment of the present disclosure, the sensor layer SSL may be omitted. In this case, the anti-reflection layer ARL may be directly located on the display panel DP. According to an embodiment of the present disclosure, locations of the sensor layer SSL and the anti-reflection layer ARL may be interchanged with each other.

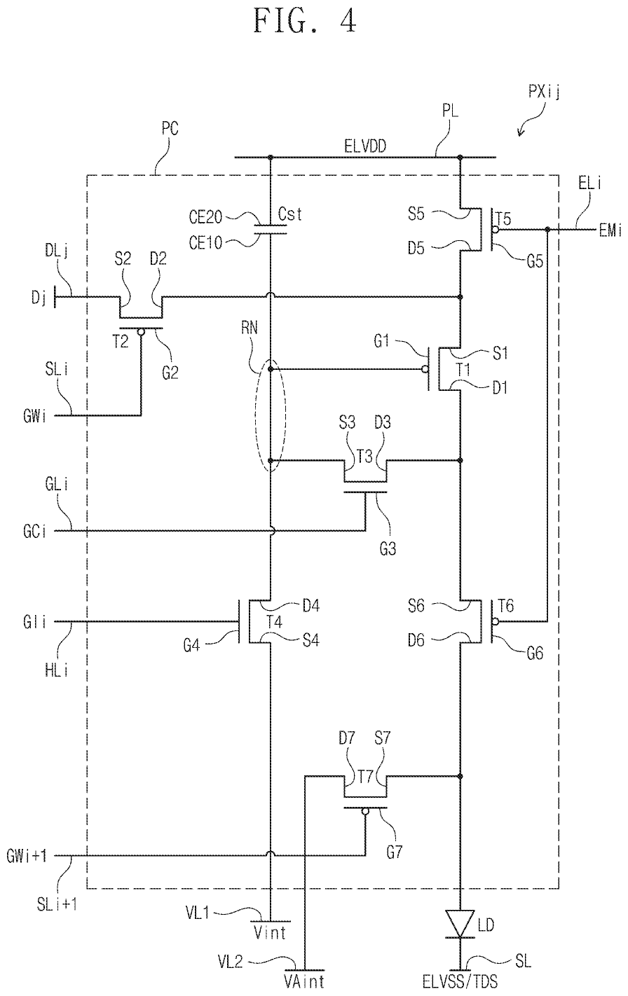

FIG. 4 is an equivalent circuit diagram of a pixel PXij, according to an embodiment of the present disclosure. FIG. 4 illustrates the pixel PXij connected to an i-th scan line SLi of a first group and connected to a j-th data line DLj. The pixel PXij may include a pixel driving circuit PC (hereinafter referred to as a “pixel circuit”) and a light emitting element LD.

According to an embodiment, the pixel circuit PC may include first to seventh transistors T1 to T7 and a capacitor Cst. According to an embodiment, it is described that the first transistor T1, the second transistor T2, and the fifth to seventh transistors T5 to T7 are P-type transistors, and the third transistor T3 and the fourth transistor T4 are N-type transistors. However, the present disclosure is not limited thereto. For example, each of the first to seventh transistors T1 to T7 may be implemented with one of a P-type transistor or an N-type transistor. An input area (or input electrode) of an N-type transistor is described as a drain (or drain area); an input area of a P-type transistor is described as a source (or source area); an output area (or output electrode) of an N-type transistor is described as a source (or source area); and, an output area of a P-type transistor is described as a drain (or drain area). Furthermore, according to an embodiment of the present disclosure, at least one of the first to seventh transistors T1 to T7 may be omitted.

According to an embodiment, the first transistor T1 may be a driving transistor, and the second transistor T2 may be a switching transistor. The capacitor Cst is electrically connected between a first voltage line PL receiving a first power supply voltage ELVDD and a reference node RN. The capacitor Cst includes a first electrode CE10 electrically connected to the reference node RN, and a second electrode CE20 electrically connected to the first voltage line PL.

The light emitting element LD is electrically connected between the first transistor T1 and a signal line SL. The signal line SL may provide a cathode of the light emitting element LD with a second power supply voltage ELVSS or a driving signal TDS. The second power supply voltage ELVSS has a lower level than the first power supply voltage ELVDD.

The first transistor T1 is electrically connected between the first voltage line PL and an anode of the light emitting element LD. A source S1 of the first transistor T1 is electrically connected to the first voltage line PL. In this specification, “being electrically connected between a transistor and a signal line or between a transistor and a transistor” means that “the source, drain, and gate of a transistor are integrated with signal lines, or connected through a connection electrode”. Another transistor may be positioned between the source S1 of the first transistor T1 and the first voltage line PL, or no transistor may be positioned between the source S1 of the first transistor T1 and the first voltage line PL.

A drain D1 of the first transistor T1 is electrically connected to the anode of the light emitting element LD. Another transistor may be positioned between the drain D1 of the first transistor T1 and the anode of the light emitting element LD, or no transistor may be positioned between the drain D1 of the first transistor T1 and the anode of the light emitting element LD. A gate G1 of the first transistor T1 is electrically connected with the reference node RN.

The second transistor T2 is electrically connected between the j-th data line DLj and the source S1 of the first transistor T1. A source S2 of the second transistor T2 is electrically connected with the j-th data line DLj, and a drain D2 of the second transistor T2 is electrically connected with the source S1 of the first transistor T1. According to an embodiment, a gate G2 of the second transistor T2 may be electrically connected to the i-th scan line SLi of a first group.

The third transistor T3 is electrically connected between the reference node RN and the drain D1 of the first transistor T1. A drain D3 of the third transistor T3 is electrically connected to the drain D1 of the first transistor T1. A source S3 of the third transistor T3 is electrically connected to the reference node RN. The third transistor T3 of a single gate is illustrated. However, the third transistor T3 may include a plurality of gates. According to an embodiment, a gate G3 of the third transistor T3 may be electrically connected to an i-th scan line GLi of a second group. The fourth transistor T4 is electrically connected between the reference node RN and a second voltage line VL1. A drain D4 of the fourth transistor T4 is electrically connected to the reference node RN, and a source S4 of the fourth transistor T4 is electrically connected to the second voltage line VL1. The fourth transistor T4 of a single gate is illustrated. However, the fourth transistor T4 may include a plurality of gates. According to an embodiment, a gate G4 of the fourth transistor T4 may be electrically connected to an i-th scan line HLi of a third group.

The fifth transistor T5 is electrically connected between the first voltage line PL and the source S1 of the first transistor T1. A source S5 of the fifth transistor T5 is electrically connected to the first voltage line PL, and a drain D5 of the fifth transistor T5 is electrically connected to the source S1 of the first transistor T1. A gate G5 of the fifth transistor T5 may be electrically connected to an i-th emission line ELi.

The sixth transistor T6 is electrically connected between the drain D1 of the first transistor T1 and the light emitting element LD. A source S6 of the sixth transistor T6 is electrically connected to the drain D1 of the first transistor T1, and a drain D6 of the sixth transistor T6 is electrically connected to the anode of the light emitting element LD. A gate G6 of the sixth transistor T6 may be electrically connected to the i-th emission line ELi. According to an embodiment of the present disclosure, differently from the gate G5 of the fifth transistor T5, the gate G6 of the sixth transistor T6 may be connected to another signal line.

The seventh transistor T7 is electrically connected between the drain D6 of the sixth transistor T6 and a third voltage line VL2. A source S7 of the seventh transistor T7 is electrically connected to the drain D6 of the sixth transistor T6, and a drain D7 of the seventh transistor T7 is electrically connected to the third voltage line VL2. A gate G7 of the seventh transistor T7 may be electrically connected to an (i+1)-th scan line SLi+1 of the first group.

When the fifth transistor T5 is turned on, the first power supply voltage ELVDD is supplied to the first transistor T1. When the sixth transistor T6 is turned on, the first transistor T1 and the light emitting element LD are electrically connected to each other. The light emitting element LD generates light of luminance corresponding to the amount of current thus received. In the meantime, this is described by way of example. A pixel circuit according to an embodiment of the present disclosure may be designed in various types, and may not be limited to an embodiment.

Additionally, although various components are illustrated in FIG. 4, embodiments according to the present disclosure are not limited to the specific components and structure illustrated in FIG. 4. For example, according to an embodiment, the pixel PXij may include additional components or fewer components without departing from the spirit and scope of embodiments according to the present disclosure.

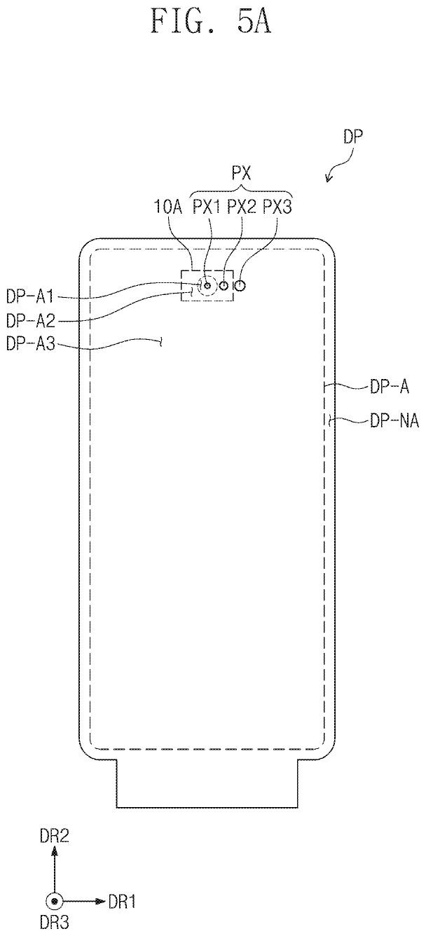

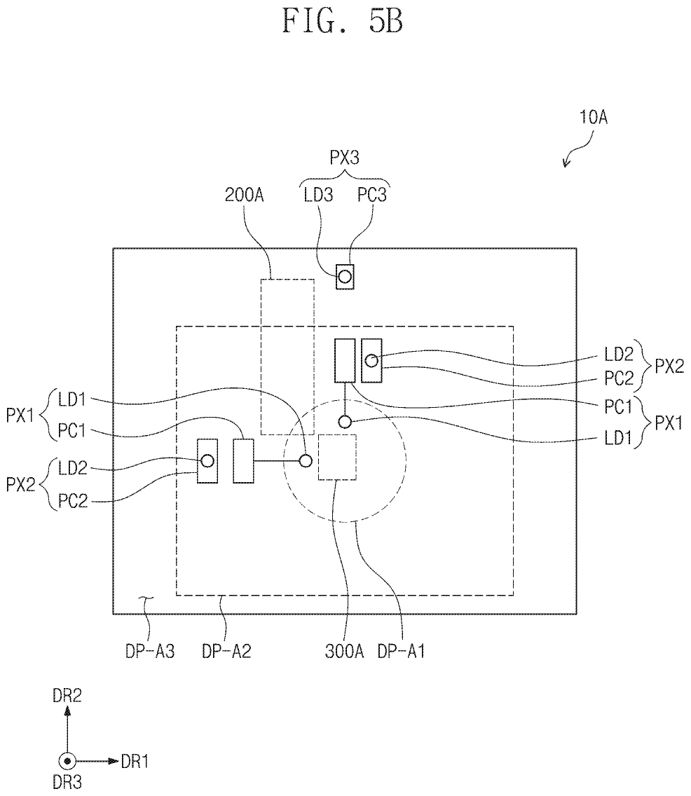

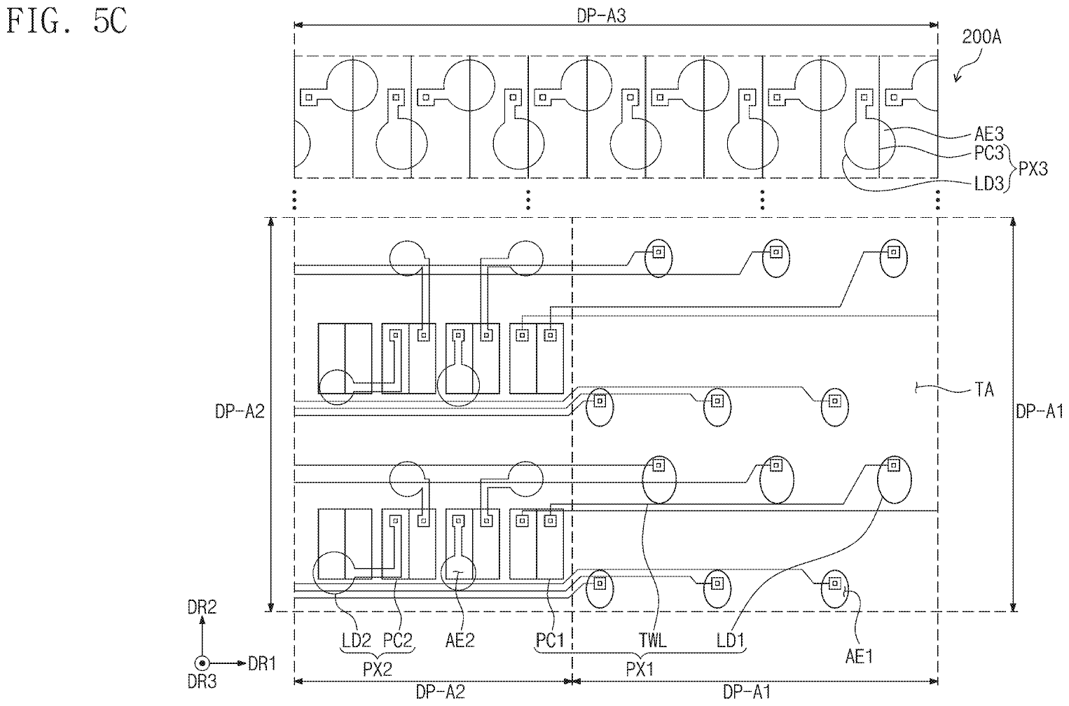

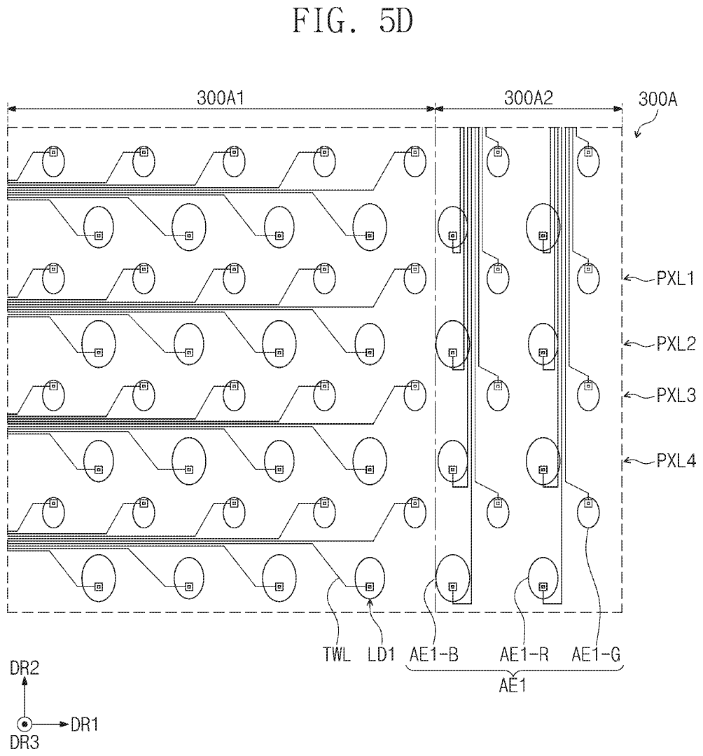

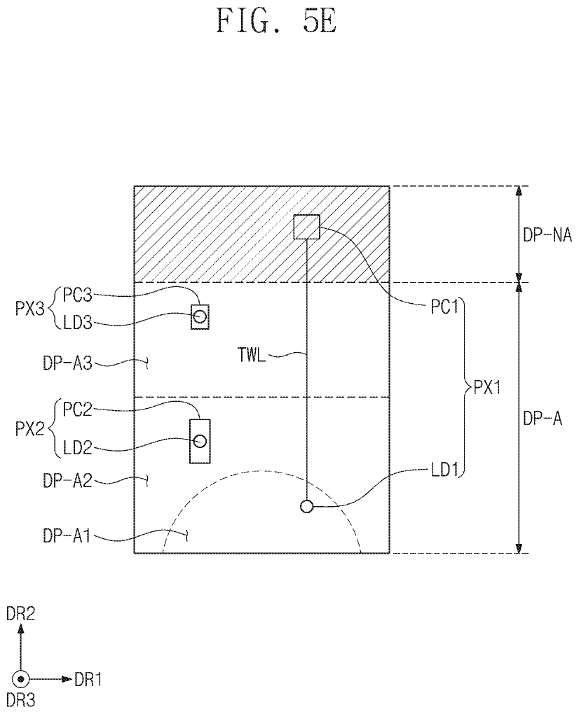

FIG. 5A is a plan view of a display panel, according to an embodiment of the present disclosure. FIG. 5B is an enlarged plan view of a portion of FIG. 5A. FIG. 5C is an enlarged plan view of a portion of FIG. 5B. FIG. 5D is an enlarged plan view of another portion of FIG. 5B. FIG. 5E is a plan view of a display panel, according to an embodiment of the present disclosure.

Referring to FIG. 5A, the display panel DP may include the display area DP-A and the peripheral area DP-NA. The peripheral area DP-NA is adjacent to the display area DP-A and may surround at least part of the display area DP-A.

The display area DP-A may include a first area DP-A1, a second area DP-A2, and a third area DP-A3. The first area DP-A1 may correspond to the sensing area 1000SA shown in FIG. 1 or the sensing area 100SA shown in FIG. 2. According to an embodiment, it is illustrated that the first area DP-A1 is in a circle shape. However, the first area DP-A1 may have various shapes, such as a polygonal shape, an oval shape, a figure having at least one curved side, or an atypical shape, and is not limited to an embodiment.

The display panel DP may include a plurality of pixels PX. The display panel DP may include a first group of pixels PX1 including light emitting elements positioned in the first area DP-A1, a second group of pixels PX2 including light emitting elements positioned in the second area DP-A2, and a third group of pixels PX3 including light emitting elements positioned in the third area DP-A3. Each of the first group of pixels PX1, the second group of pixels PX2, and the third group of pixels PX3 may include the pixel circuit PC shown in FIG. 4. Locations of the first group of pixels PX1, the second group of pixels PX2, and the third group of pixels PX3 shown in FIG. 5A are illustrated based on a location of the corresponding light emitting element LD (see FIG. 4).

Each of the first group of pixels PX1, the second group of pixels PX2, and the third group of pixels PX3 may include a plurality of pixels. In this case, each of the first to third groups of pixels PX1, PX2, and PX3 may include a red pixel, a green pixel, and a blue pixel, and may further include a white pixel according to an embodiment.

The first area DP-A1, the second area DP-A2, and the third area DP-A3 may be distinguished from each other by transmittance. The transmittance is measured based on a reference area size.

The first area DP-A1 may have higher transmittance than the second area DP-A2 and the third area DP-A3. The reason is that the first area DP-A1 has a lower occupied area ratio of a light-shielding structure described later than the second area DP-A2 and the third area DP-A3. A non-occupied area of the light-shielding structure corresponds to a transmission area of an optical signal. The light-shielding structure may include a conductive pattern of a circuit layer, a pixel defining layer, and a pixel defining pattern, which will be described later.

When the first area DP-A1, the second area DP-A2, and the third area DP-A3 are classified based on the transmittance, the first area DP-A1 may be an area having first transmittance, and the second area DP-A2 and the third area DP-A3 may be different portions among areas having second transmittance different from the first transmittance. That is, according to an embodiment, the transmittance of the second area DP-A2 may be substantially the same as the transmittance of the third area DP-A3. However, because the transmittance of the first area DP-A1 is significantly higher than that of each of the second area DP-A2 and the third area DP-A3 even when the transmittance of the second area DP-A2 is not the same as the transmittance of the third area DP-A3, the second area DP-A2 and the third area DP-A3 may be defined as areas having the second transmittance when the first area DP-A1 is defined as an area having the first transmittance.

In the meantime, in the display panel DP according to an embodiment, the first area DP-A1, the second area DP-A2, and the third area DP-A3 may be classified based on resolution. The resolution is measured based on a reference area size. On the basis of the resolution, the first area DP-A1 and the second area DP-A2 may be different portions of areas having first resolution, and the third area DP-A3 may be an area having second resolution different from the first resolution. For example, the number of light emitting elements per reference area size of the first area DP-A1 may be substantially the same as the number of light emitting elements per reference area size of the second area DP-A2. The number of light emitting elements per reference area size of the first area DP-A1 may be different from the number of light emitting elements per reference area size of the third area DP-A3.

Referring to FIG. 5B, the first group of pixels PX1 may include a first light emitting element LD1 and a first pixel circuit PC1 electrically connected to the first light emitting element LD1. The second group of pixels PX2 may include a second light emitting element LD2 and a second pixel circuit PC2 for driving the second light emitting element LD2. The third group of pixels PX3 of may include a third light emitting element LD3 and a third pixel circuit PC3 for driving the third light emitting element LD3.

According to an embodiment, the first light emitting element LD1 is positioned in the first area DP-A1, and the first pixel circuit PC1 is positioned in the second area DP-A2. The second light emitting element LD2 and the second pixel circuit PC2 are located in the second area DP-A2. The third light emitting element LD3 and the third pixel circuit PC3 are located in the third area DP-A3.

The first pixel circuit PC1 may be located in the second area DP-A2 to be spaced from the first light emitting element LD1. Accordingly, the first area DP-A1 may include an area where a pixel circuit is not positioned, and thus the first area DP-A1 may have higher transmittance than an area (e.g. the second area DP-A2 or the third area DP-A3) where the pixel circuit is positioned. An occupancy ratio of a transmission area within the first area DP-A1 may be increased by removing a light-shielding structure such as a transistor. As a result, the transmittance of the first area DP-A1 may be improved.

FIG. 5B shows the first groups of pixels PX1 having two types. The one first group of pixels PX1 includes the first light emitting element LD1 that is positioned spaced from the first pixel circuit PC1 in the first direction DR1. The other first group of pixels PX1 includes the first light emitting element LD1 that is positioned spaced from the first pixel circuit PC1 in the second direction DR2. According to an embodiment, similarly to the first group of pixels PX1 positioned on a left side of the first area DP-A1, the first group of pixels PX1 positioned on a right side of the first area DP-A1 may have an arrangement relationship between the first light emitting element LD1 and the first pixel circuit PC1. Moreover, similarly to the first group of pixels PX1 positioned on an upper side of the first area DP-A1, the first group of pixels PX1 positioned on a lower side of the first area DP-A1 may have an arrangement relationship between the first light emitting element LD1 and the first pixel circuit PC1.

In FIG. 5C, anodes (or first electrodes AE1, AE2, and AE3) of light emitting elements are shown on behalf of the first light emitting element LD1, the second light emitting element LD2, and the third light emitting element LD3, respectively. As shown in FIG. 5C, the anode AE1 of the first light emitting element LD1 may have a smaller area size than the anode AE3 of the third light emitting element LD3. According to an embodiment, the anode AE1 of the first light emitting element LD1 may have an area size of about ½ to ⅓ of that of the anode AE3 of the third light emitting element LD3.

An area, in which the first light emitting element LD1 is not positioned, from among the first area DP-A1 may be defined as a transmission area TA. For example, in the first area DP-A1, an area in which the anode AE1 of the first light emitting element LD1 is not positioned may be defined as the transmission area TA. According to an embodiment of the present disclosure, as compared with the transmittance of the third area DP-A3, the transmittance of the first area DP-A1 may be improved by designing an area size of the anode AE1 of the first light emitting element LD1 to be smaller than an area size of the anode AE3 of the third light emitting element LD3.

The first light emitting element LD1 may be electrically connected to the first pixel circuit PC1 through a pixel connection line TWL. The pixel connection line TWL overlaps the first area DP-A1 and the second area DP-A2. The pixel connection line TWL may overlap the transmission area TA.

In the meantime, the first light emitting element LD1 according to an embodiment of the present disclosure includes a plurality of light emitting layers. Because the first light emitting element LD1 may have a higher lifetime than a light emitting element including a single light emitting layer, the first light emitting element LD1 may have an equivalent lifetime even with a relatively small area size as compared to the light emitting element including a single light emitting layer. According to an embodiment of the present disclosure, issues on lifetime degradation of the first light emitting element LD1 in the first area DP-A1 may be improved by forming the first light emitting element LD1 in a structure having a high lifetime. In addition, light transmittance in the first area DP-A1 may be improved by reducing the area size of the first light emitting element LD1. This will be more fully described later.

The anode AE2 of the second light emitting element LD2 may have a smaller area size than the anode AE3 of the third light emitting element LD3. However, this is illustrated by way of example. The anode AE2 of the second light emitting element LD2 may have the same area size as that of the third light emitting element LD3, and is not limited to an embodiment.

In the meantime, to improve the transmittance of the first area DP-A1, the first light emitting elements LD1 within the reference area size may be positioned such that the number of the first light emitting elements LD1 is less than the number of the third light emitting elements LD3. For example, the resolution of the first area DP-A1 is approximately ½, ⅜, ⅓, ¼, 2/9, ⅛, 1/9, 1/16, or the like of the resolution of the third area DP-A3. For example, the resolution of the third area DP-A3 may be about 400 ppi or higher, and the resolution of the first area DP-A1 may be about 200 ppi or 100 ppi. However, this is only an example and is not particularly limited thereto.

To secure an area where the first pixel circuit PC1 is to be positioned in the second area DP-A2, the second light emitting elements LD2 within a reference area size may be positioned such that the number of second light emitting elements LD2 is less than the number of third light emitting elements LD3. Within the second area DP-A2, the first pixel circuit PC1 may be located in an area where the second pixel circuit PC2 is not positioned.

In the meantime, the anodes AE1, AE2, and AE3 may have curved edges. The anodes AE1, AE2, and AE3 having curved edges may minimize the diffraction of light. In particular, the anode AE1 of the first light emitting element LD1 may minimize the diffraction of light passing through a transmission area. However, this is illustrated by way of example, and shapes of the anodes AE1, AE2, and AE3 may be variously changed, and may not be limited to an embodiment.

Referring to FIG. 5D, the first light emitting elements LD1 having three colors are shown. One anode AE1-R, another anode AE1-G, and the other anode AE1-B are shown on behalf of the first light emitting element LD1 of the first color, the first light emitting element LD1 of the second color, and the first light emitting element LD1 of the third color, respectively. Hereinafter, the anodes AE1-R, AE1-G, and AE1-B of the first light emitting elements having the first or third colors are called the first color anode AE1-R, the second color anode AE1-G, and the third color anode AE1-B, respectively. The first color may be red, the second color may be green, and the third color may be blue, but embodiments according to the present disclosure are not limited thereto. For example, the first to third colors may be adopted as three other main colors, or each of the first to third colors may be adopted as white, but embodiments according to the present disclosure are not limited thereto.

FIG. 5D shows first to fourth light emitting element rows PXL1 to PXL4 located in the first area DP-A1. In each of the first and third light emitting element rows PXL1 and PXL3, second color anodes AE1-G may be arranged in the first direction DR1. In each of the second and fourth light element rows PXL2 and PXL4, the first color anodes AE1-R and the third color emitting anodes AE1-B may be alternately arranged in the first direction DR1. The first color anode AE1-R of the second light emitting element row PXL2 is aligned with the third color anode AE1-B of the fourth light emitting element row PXL4 in the second direction DR2. The arrangement of the first to fourth light emitting element rows PXL1 to PXL4 may be expanded to the second area DP-A2 and the third area DP-A3.

In the meantime, according to an embodiment, the second area DP-A2 or the third area DP-A3 shown in FIGS. 5A to 5C may also have the same pixel arrangement as the pixel arrangement of the first to fourth light emitting element rows PXL1 to PXL4.

In FIG. 5D, the anodes AE1-R, AE1-G, and AE1-B arranged in a partial area 300A1 correspond to anodes of the pixels PX1 of the first group arranged on a left side of the first area DP-A1 shown in FIG. 5B, and the anodes AE1-R, AE1-G, and AE1-B arranged in the other partial area 300A2 correspond to anodes of the pixels PX1 of the first group arranged on an upper side of the first area DP-A1 shown in FIG. 5B. As shown in FIG. 5D, it may be seen that an extension direction of the pixel connection line TWL is different depending on locations of the anodes AE1-R, AE1-G, and AE1-B within the first area DP-A1. According to an embodiment of the present disclosure, interference between pixel connection lines TWL may be prevented by differently designing the shape of the pixel connection line TWL depending on the locations of the anodes AE1-R, AE1-G, and AE1-B. Accordingly, efficient arrangement of the anodes AE1-R, AE1-G, and AE1-B within the first area DP-A1 may be possible.

In the meantime, as illustrated in FIG. 5E, according to an embodiment of the present disclosure, the first pixel circuit PC1 may be located in a fourth area other than the first area DP-A1, the second area DP-A2, and the third area DP-A3. According to an embodiment, the first pixel circuit PC1 may be positioned in the peripheral area DP-NA. In this case, the pixel connection line TWL overlaps the first area DP-A1, the second area DP-A2, the third area DP-A3, and the peripheral area DP-NA. According to an embodiment of the present disclosure, as long as the first pixel circuit PC1 is capable of being positioned in an area other than the first area DP-A1 while being spaced from the first light emitting element LD1, the first pixel circuit PC1 may be positioned at various locations, and is not limited to an embodiment.

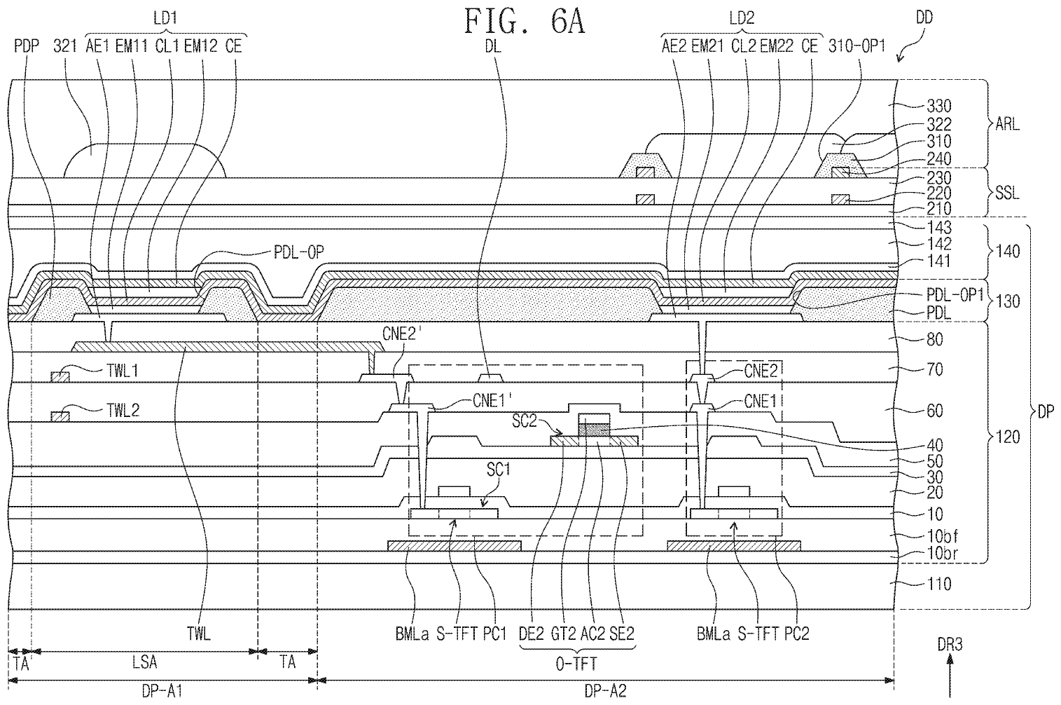

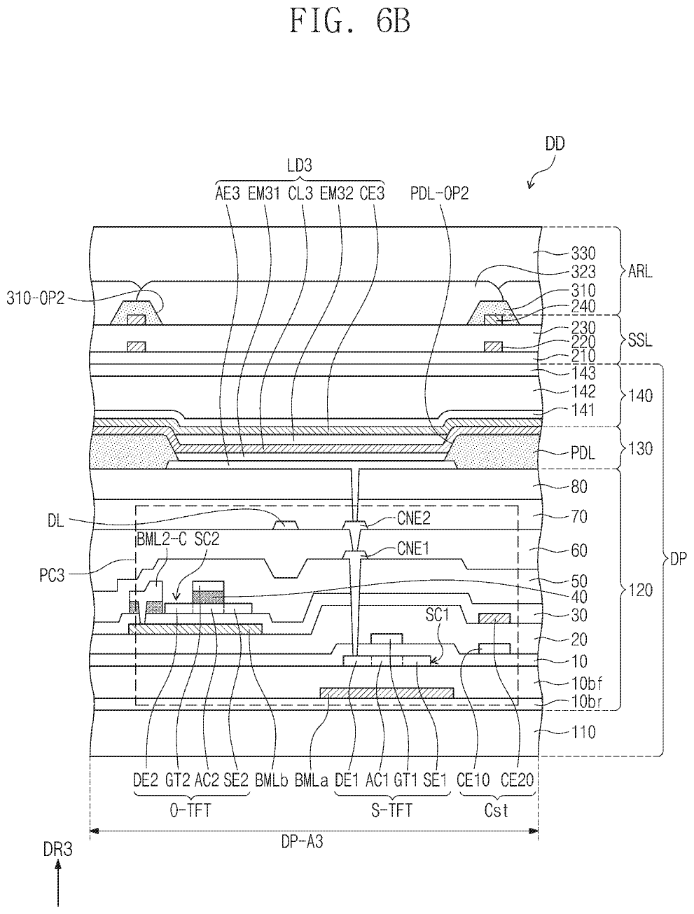

FIG. 6A is a cross-sectional view corresponding to the first area DP-A1 and the second area DP-A2 of a display device, according to an embodiment of the present disclosure. FIG. 6B is a cross-sectional view corresponding to the third area DP-A3 of the display device DD, according to an embodiment of the present disclosure.

FIG. 6A shows the first light emitting element LD1, and a silicon transistor S-TFT and an oxide transistor O-TFT of the first pixel circuit PC1. In an equivalent circuit shown in FIG. 4, each of the third and fourth transistors T3 and T4 may be the oxide transistor O-TFT, and each of the remaining transistors may be the silicon transistor S-TFT. In FIG. 6A, the first light emitting element LD1 and a part of the first pixel circuit PC1 are shown, and the second light emitting element LD2 and a part of the second pixel circuit PC2 are shown. In the meantime, unlike the first pixel circuit PC1, the oxide transistor O-TFT of the second pixel circuit PC2 is not shown. The silicon transistor S-TFT shown in FIG. 6A may be the sixth transistor T6 shown in FIG. 4. FIG. 6B shows the third light emitting element LD3, and the silicon transistor S-TFT and the oxide transistor O-TFT of the third pixel circuit PC3 located in the third area DP-A3. Detailed configurations of the silicon transistor S-TFT are shown in FIG. 6B. While reference numerals of the configurations of the silicon transistor S-TFT are omitted, FIG. 6A illustrates the configurations of the silicon transistor S-TFT. Hereinafter, the present disclosure will be described with reference to FIGS. 6A and 6B.

A barrier layer 10br may be located on the base layer 110. The barrier layer 10br prevents or reduces instances of foreign objects or contaminants being introduced from the outside. The barrier layer 10br may include at least one inorganic layer. The barrier layer 10br may include a silicon oxide layer and a silicon nitride layer. Each of the silicon oxide layer and the silicon nitride layer may include a plurality of layers, and the plurality of silicon oxide layers and the silicon nitride layers may be alternately stacked.

A first shielding electrode BMLa may be located on the barrier layer 10br. The first shielding electrode BMLa may include metal. The first shielding electrode BMLa may include molybdenum (Mo) having good heat resistance, an alloy containing molybdenum, titanium (Ti), or an alloy containing titanium. The first shielding electrode BMLa may receive a bias voltage. The first shielding electrode BMLa may receive the first power supply voltage ELVDD. The first shielding electrode BMLa may block an electric potential due to polarization from affecting the silicon transistor S-TFT. The first shielding electrode BMLa may block external light from reaching the silicon transistor S-TFT. According to an embodiment of the present disclosure, the first shielding electrode BMLa may be a floating electrode in a form isolated from another electrode or a wire.

A buffer layer 10bf may be located on the barrier layer 10br. The buffer layer 10bf may prevent or reduce instances of metal atoms, contaminants, or impurities being spread from the base layer 110 to a first semiconductor pattern SC1 located on the buffer layer 10bf. The buffer layer 10bf may include at least one inorganic layer. The buffer layer 10bf may include a silicon oxide layer and a silicon nitride layer.

The first semiconductor pattern SC1 may be located on the buffer layer 10bf. The first semiconductor pattern SC1 may include a silicon semiconductor. For example, the silicon semiconductor may include amorphous silicon, or polycrystalline silicon. For example, the first semiconductor pattern SC1 may include low-temperature polysilicon.

FIG. 6A only shows a portion of the first semiconductor pattern SC1, and the first semiconductor pattern SC1 may be further located in another area. The first semiconductor pattern SC1 may be arranged across pixels in a specific rule. An electrical property of the first semiconductor pattern SC1 may vary depending on whether the first semiconductor pattern SC1 is doped or not. The first semiconductor pattern SC1 may include a first area having high conductivity and a second area having low conductivity. The first area may be doped with an N-type dopant or a P-type dopant. A P-type transistor may include a doping area doped with the P-type dopant, and an N-type transistor may include a doping area doped with the N-type dopant. The second area may be an undoped area or an area doped with a concentration lower than a concentration in the first area.

The conductivity of the first area is greater than the conductivity of the second area. The first area may substantially serve as an electrode or a signal line. The second area may substantially correspond to a channel area (or an active area) of a transistor. In other words, a part of the first semiconductor pattern SC1 may be a channel area of a transistor. Another part thereof may be a source or drain of the transistor. Another part thereof may be a connection electrode or a connection signal line.

A source area SE1, a channel area AC1 (or an active area), and a drain area DE1 of the silicon transistor S-TFT may be formed from the first semiconductor pattern SC1. The source area SE1 and the drain area DE1 may respectively extend in directions opposite to each other from the channel area AC1, when viewed in a cross-sectional view.

A first insulating layer 10 may be located on the buffer layer 10bf. The first insulating layer 10 may cover the first semiconductor pattern SC1. The first insulating layer 10 may be an inorganic layer. The first insulating layer 10 may include at least one of aluminum oxide, titanium oxide, silicon oxide, silicon nitride, silicon oxynitride, zirconium oxide, or hafnium oxide.

The first insulating layer 10 may be a silicon oxide layer having a single layer structure. An inorganic layer of the circuit layer 120 to be described below, not the first insulating layer 10, may have a single layer structure or a multi-layer structure and may include at least one of the above materials, but embodiments according to the present disclosure are not limited thereto.

A gate GT1 of the silicon transistor S-TFT is located on the first insulating layer 10. The gate GT1 may be a part of a metal pattern. The gate GT1 overlaps the channel area AC1. In a process of doping the first semiconductor pattern SC1, the gate GT1 may be a mask. The gate GT1 may include molybdenum (Mo) having good heat resistance, an alloy containing molybdenum, titanium (Ti), an alloy containing titanium, and the like, but is not particularly limited thereto.

Referring to FIG. 6B, the first electrode CE10 of the storage capacitor Cst is located on the first insulating layer 10. In the meantime, differently from that shown in FIG. 6B, the first electrode CE10 may be integrated with the gate GT1.

Returning to FIGS. 6A and 6B, a second insulating layer 20 is located on the first insulating layer 10 and may cover the gate GT1. According to an embodiment, the display device DD may further comprises an upper electrode overlapping the gate GT1 located on the second insulating layer 20. The second electrode CE20 overlapping the first electrode CE10 may be located on the second insulating layer 20. Differently from that shown in FIG. 6B, the second electrode CE20 may be integrated with the upper electrode UE. Each of the second electrode CE20 and the upper electrode UE may include molybdenum (Mo) having good heat resistance, an alloy containing molybdenum, titanium (Ti), or an alloy containing titanium.

A second shielding electrode BMLb is located on the second insulating layer 20. The second shielding electrode BMLb may be arranged to correspond to a lower portion of the oxide transistor O-TFT. According to an embodiment of the present disclosure, the second shielding electrode BMLb may be omitted. According to an embodiment of the present disclosure, the first shielding electrode BMLa may extend to the lower portion of the oxide transistor O-TFT to replace the second shielding electrode BMLb.

A third insulating layer 30 may be located on the second insulating layer 20. A second semiconductor pattern SC2 may be located on the third insulating layer 30. The second semiconductor pattern SC2 may include a channel area AC2 of the oxide transistor O-TFT. The second semiconductor pattern SC2 may include an oxide semiconductor. The second semiconductor pattern SC2 may include transparent conductive oxide (TCO) such as indium tin oxide (ITO), indium zinc oxide (IZO), indium gallium zinc oxide (IGZO), zinc oxide (ZnOx) or indium oxide (In₂O₃).

The oxide semiconductor may include a plurality of areas that are distinguished from one another depending on whether TCO is reduced. An area (hereinafter referred to as a “reduction area”) in which TCO is reduced has higher conductivity than an area (hereinafter referred to as a “non-reduction area”) in which TCO is not reduced. The reduction area substantially serves as a source area/drain area of the transistor or a signal line. The non-reduction area substantially corresponds to a semiconductor area (or channel) of a transistor. In other words, a partial area of the second semiconductor pattern SC2 may be a semiconductor area of a transistor; another partial area thereof may be the source area/drain area of the transistor; and another partial area thereof may be a signal transmission area.

A fourth insulating layer 40 may be located on the third insulating layer 30. As shown in FIGS. 6A and 6B, the fourth insulating layer 40 may be an insulating pattern that overlaps a gate GT2 of the oxide transistor O-TFT and is exposed by a source area SE2 and a drain area DE2 of the oxide transistor O-TFT. According to an embodiment of the present disclosure, the fourth insulating layer 40 may overlap a plurality of pixels in common and may cover the second semiconductor pattern SC2.

The gate GT2 of the oxide transistor O-TFT is located on the fourth insulating layer 40. The gate GT2 of the oxide transistor O-TFT may be a portion of a metal pattern. The gate GT2 of the oxide transistor O-TFT overlaps the channel area AC2. The gate GT2 may include molybdenum (Mo) having good heat resistance, an alloy containing molybdenum, titanium (Ti), or an alloy containing titanium. The gate GT2 may include a titanium layer and a molybdenum layer located on the titanium layer.

A fifth insulating layer 50 may be located on the fourth insulating layer 40, and the fifth insulating layer 50 may cover the gate GT2. Each of the first to fifth insulating layers 10 to 50 may be an inorganic layer.

A first connection electrode CNE1 may be located on the fifth insulating layer 50. The first connection electrode CNE1 may be connected to the drain area DE1 of the silicon transistor S-TFT through a contact hole passing through the first, second, third, and fifth insulating layers 10, 20, 30, and 50.

A sixth insulating layer 60 may be located on the fifth insulating layer 50. A second connection electrode CNE2 may be located on the sixth insulating layer 60. The second connection electrode CNE2 may be connected to the first connection electrode CNE1 through a contact hole passing through the sixth insulating layer 60. The data line DL may be located on the sixth insulating layer 60. A seventh insulating layer 70 may be located on the sixth insulating layer 60 and may cover the second connection electrode CNE2 and the data line DL. An eighth insulating layer 80 may be located on the seventh insulating layer 70. The first connection electrode CNE1, the second connection electrode CNE2, and the data line DL may include molybdenum, silver, titanium, copper, aluminum, or an alloy thereof.

Each of the sixth insulating layer 60, the seventh insulating layer 70, and the eighth insulating layer 80 may be an organic layer. For example, each of the sixth insulating layer 60, the seventh insulating layer 70, and the eighth insulating layer 80 may include general purpose polymers such as Benzocyclobutene (BCB), polyimide, Hexamethyldisiloxane (HMDSO), Polymethylmethacrylate (PMMA) or Polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and the blend thereof.

The anode AE1 of the first light emitting element LD1 may be electrically connected to the first pixel circuit PC1 located in the second area DP-A2. The anode AE1 of the first light emitting element LD1 may be electrically connected to the silicon transistor S-TFT or the oxide transistor O-TFT. FIG. 6A illustrates the anode AE1 of the first light emitting element LD1 connected to the silicon transistor S-TFT.

The anode AE1 of the first light emitting element LD1 may be electrically connected to the first pixel circuit PC1 through the pixel connection line TWL and connection electrodes CNE1′ and CNE2′. According to an embodiment of the present disclosure, one of the connection electrodes CNE1′ and CNE2′ may be omitted.

The pixel connection line TWL may include a transparent conductive material. For example, the pixel connection line TWL may include TCO such as indium tin oxide (ITO), indium zinc oxide (IZO), indium gallium zinc oxide (IGZO), zinc oxide (ZnOx) or indium oxide (In₂O₃). Even though the pixel connection line TWL overlaps the transmission area TA through which an optical signal passes, the pixel connection line TWL thus transparent may minimize the distortion of the optical signal such as diffraction.

According to an embodiment, the connection line TWL (hereafter referred to as a “first pixel connection line”) overlaps the first area DP-A1 and the second area DP-A2 and is interposed between the seventh insulating layer 70 and the eighth insulating layer 80. The first pixel connection line TWL does not overlap the third area DP-A3 (see FIG. 6B).

According to an embodiment of the present disclosure, the display panel DP may further include a connection line TWL1 (hereinafter referred to as a “second pixel connection line”) interposed between the sixth insulating layer 60 and the seventh insulating layer 70 or a connection line TWL2 (hereinafter referred to as a “third pixel connection line”) interposed between the fifth insulating layer 50 and the sixth insulating layer 60. According to an embodiment of the present disclosure, the display panel DP may include one or more of first, second, and third pixel connection lines TWL, TWL1, and TWL2.

The first light emitting element LD1 may include a plurality of light emitting layers. In detail, the first light emitting element LD1 may include the anode AE1 (or a first electrode), a first light emitting layer EM11, a charge generation layer CL1, a second light emitting layer EM12, and a cathode CE (or a second electrode). The cathode CE of each of the second light emitting element LD2 and the third light emitting element LD3, which will be described later, may be integrated with the cathode CE of the first light emitting element LD1. That is, the cathode CE may be provided in common to the first light emitting element LD1, the second light emitting element LD2, and the third light emitting element LD3.

The anode AE1 of the first light emitting element LD1 may be located on the eighth insulating layer 80. The anode AE1 of the first light emitting element LD1 may be a (semi)-transmissive electrode or a reflective electrode depending on the emission type of the first light emitting element LD1. According to an embodiment of the present disclosure, the anode AE1 of the first light emitting element LD1 may include a reflective layer formed of Ag, Mg, Al, Pt, Pd, Au, Ni, Nd, Ir, Cr, or a compound thereof, and a transparent electrode or semi-transparent electrode layer formed on the reflective layer. The transparent or semi-transparent electrode layer may include at least one selected from a group including indium tin oxide (ITO), indium zinc oxide (IZO), indium gallium zinc oxide (IGZO), zinc oxide (ZnOx) or indium oxide (In₂O₃), and aluminum-doped zinc oxide (AZO). For example, the anode AE1 of the first light emitting element LD1 may include a stacked structure of ITO/Ag/ITO.

According to an embodiment of the present disclosure, the first light emitting layer EM11 and the second light emitting layer EM12 may generate light of the same color as each other. The same color means substantially the same color to be displayed, and is not limited to the same peak wavelength. Accordingly, the first light emitting layer EM11 emits light of substantially the same color as the second light emitting layer EM12, and the peak wavelength of light generated from the first light emitting layer EM11 may be the same as the peak wavelength of light generated from the second light emitting layer EM12 or may be shifted by a range (e.g., a set or predetermined range). However, this is illustrated by way of example. In the first light emitting element LD1, the first light emitting layer EM11 and the second light emitting layer EM12 may respectively generate lights of different colors from each other. In this case, the first light emitting element LD1 may generate light having a mixed color and is not limited to an embodiment.

The charge generation layer CL1 is interposed between the first light emitting layer EM11 and the second light emitting layer EM12. The charge generation layer CL1 may provide electrons to the first light emitting layer EM11 or may provide holes to the second light emitting layer EM12. The charge generation layer CL1 may be a single layer or may have a multi-layer structure in which a P-dopant layer and an N-dopant layer are stacked. For example, the charge generation layer CL1 may be a multi-layer in which a P-dopant layer and an N-dopant layer are sequentially stacked.

The cathode CE may be a (semi)-transmissive electrode or a reflective electrode depending on the emission type of the first light emitting element LD1. For example, the cathode CE may include one of metal, an alloy, metal nitride, metal fluoride, conductive metal oxide, or a combination thereof.

Meanwhile, according to an embodiment, a hole control area may be interposed between the anode AE1 and the first light emitting layer EM11 and between the charge generation layer CL1 and the second light emitting layer EM12. The hole control area may include a hole transport layer and may further include a hole injection layer. As needed, the hole control area may further include a hole buffer layer or an electron blocking layer. An electronic control area may be interposed between the second light emitting layer EM12 and the cathode CE and between the charge generation layer CL1 and the first light emitting layer EM11. The electron control area may include an electron transport layer and may further include an electron injection layer. As needed, the electron control area may further include an electron buffer layer or a hole blocking layer.

According to an embodiment, it may be described that the first light emitting element LD1 has a structure including at least two light emitting units. For example, the anode AE1, the first light emitting layer EM11, and the charge generation layer CL1 (or an N-dopant layer among charge generation layers) may constitute one light emitting unit. The charge generation layer CL1 (or a P-dopant layer among charge generation layers), the second light emitting layer EM12, and the cathode CE may constitute another light emitting unit. As the first light emitting element LD1 has a structure including a plurality of light emitting units, the first light emitting element LD1 may generate light of higher luminance than a light emitting element including a single light emitting unit. In addition, as the first light emitting element LD1 has a structure including a plurality of light emitting units, partial deterioration may be prevented or reduced even when there is an increase in a driving current to increase luminance. Accordingly, even when the anode AE1 of the first light emitting element LD1 is provided with a small area size, issues on lifetime degradation may be prevented or reduced. This will be more fully described later.

Each of the second light emitting element LD2 and the third light emitting element LD3 may have the same structure as that of the first light emitting element LD1. For example, the second light emitting element LD2 includes the anode AE2, a first light emitting layer EM21, a charge generation layer CL2, a second light emitting layer EM22, and the cathode CE, and the third light emitting element LD3 includes the anode AE3, a first light emitting layer EM31, a charge generation layer CL3, a second light emitting layer EM32, and the cathode CE3. Accordingly, each of the second light emitting element LD2 and the third light emitting element LD3 may have a structure including two light emitting units. However, this is illustrated by way of example. Each of the second light emitting element LD2 and the third light emitting element LD3 may have a structure different from that of the first light emitting element LD1, and is not limited to an embodiment.

A pixel defining layer PDL may be located on the eighth insulating layer 80. The pixel defining layer PDL may have a property of absorbing light. For example, the pixel defining layer PDL may have a black color. The pixel defining layer PDL may include a black coloring agent. The black coloring agent may include a black dye and a black pigment. The black coloring agent may include carbon black, a metal such as chromium, or an oxide thereof. The pixel defining layer PDL may correspond to a light shielding pattern having light shielding characteristics.

The pixel defining layer PDL may not overlap the first area DP-A1. For example, an opening PDL-OP exposing the first area DP-A1 may be defined in the pixel defining layer PDL. The pixel defining layer PDL may cover a portion of the anode AE2 of the second light emitting element LD2 in the second area DP-A2. For example, a first opening PDL-OP1 exposing a portion of the anode AE2 of the second light emitting element LD2 may be defined in the pixel defining layer PDL. The pixel defining layer PDL may increase a distance between the edge of the anode AE2 of the second light emitting element LD2 and the cathode CE. Accordingly, instances of an electric arc occurring at the edge of the anode AE1 by the pixel defining layer PDL may be prevented or reduced. Besides, referring to FIG. 6B, the pixel defining layer PDL may cover a portion of the anode AE3 of the third light emitting element LD3. For example, a second opening PDL-OP2 exposing a portion of the anode AE3 of the third light emitting element LD3 may be defined in the pixel defining layer PDL.

Returning to FIG. 6A, the display panel DP according to an embodiment of the present disclosure may include a pixel defining pattern PDP. The pixel defining pattern PDP may be located on the eighth insulating layer 80 to overlap the first area DP-A1. The pixel defining pattern PDP includes the same material as the pixel defining layer PDL and may be formed through the same process. The pixel defining pattern PDP may cover a portion of the anode AE1 of the first light emitting element LD1. An opening PDP-OP exposing a portion of the anode AE1 of the first light emitting element LD1 may be defined in the pixel defining pattern PDP.

According to an embodiment, it is described that the pixel defining pattern PDP is distinguished from the pixel defining layer PDL. However, the pixel defining pattern PDP may be treated as a portion of the pixel defining layer PDL. The pixel defining layer PDL may be defined as a first portion of a patterned insulating layer, and the pixel defining pattern PDP may be defined as a second portion of the patterned insulating layer. An insulating layer including the pixel defining pattern PDP and the pixel defining layer PDL may include an organic layer.

The pixel defining pattern PDP may cover the edge of the anode AE1 of the first light emitting element LD1, and may suppress the generation of an electric arc like the pixel defining layer PDL. An area overlapping a portion where the pixel defining pattern PDP and the anode AE1 of the first light emitting element LD1 are positioned in the first area DP-A1 may be defined as a light shielding area LSA, and the remaining area may be defined as the transmission area TA. The encapsulation layer 140 may be located on the light emitting element layer 130. The encapsulation layer 140 may include an inorganic layer 141, an organic layer 142, and an inorganic layer 143, which are sequentially stacked, but layers constituting the encapsulation layer 140 are not limited thereto.

The inorganic layer 141 and the inorganic layer 143 may protect the light emitting element layer 130 from moisture and oxygen, and the organic layer 142 may protect the light emitting element layer 130 from a foreign substance such as dust particles. The inorganic layer 141 and the inorganic layer 143 may include a silicon nitride layer, a silicon oxynitride layer, a silicon oxide layer, a titanium oxide layer, or an aluminum oxide layer. The organic layer 142 may include, but is not limited to, an acryl-based organic layer.

The sensor layer SSL may be located on the display panel DP. The sensor layer SSL may include at least one conductive layer and at least one insulating layer. According to an embodiment, the sensor layer SSL may include a first insulating layer 210, a first conductive layer 220, a second insulating layer 230, and a second conductive layer 240.

The first insulating layer 210 may be directly located on the display panel DP. The first insulating layer 210 may be an inorganic layer including at least one of silicon nitride, silicon oxynitride, or silicon oxide. Alternatively, the first insulating layer 210 may be an organic layer including an epoxy resin, an acrylate resin, or an imide-based resin. The first insulating layer 210 may have a single layer structure or may have a multi-layer structure stacked in the third direction DR3.

Each of the first conductive layer 220 and the second conductive layer 240 may have a single layer structure or may have a multi-layer structure stacked in the third direction DR3. The first conductive layer 220 and the second conductive layer 240 may include conductive lines defining mesh-shaped electrodes. The conductive line of the first conductive layer 220 and the conductive line of the second conductive layer 240 may be connected through a contact hole passing through the second insulating layer 230, or the conductive line of the first conductive layer 220 may not be connected to the conductive line of the second conductive layer 240. A connection relationship between a conductive line of the first conductive layer 220 and a conductive line of the second conductive layer 240 may be determined depending on the type of a sensor formed as the sensor layer SSL.

Each of the first conductive layer 220 and the second conductive layer 240 of a single layer structure may include a metal layer or a transparent conductive layer. The metal layer may include molybdenum, silver, titanium, copper, aluminum, or an alloy thereof. The transparent conductive layer may include TCO such as indium tin oxide (ITO), indium zinc oxide (IZO), zinc oxide (ZnOx), or indium zinc tin oxide (IZTO). Besides, the transparent conductive layer may include a conductive polymer such as PEDOT, a metal nano wire, graphene, and the like.

Each of the first conductive layer 220 and the second conductive layer 240 of the multi-layer structure may include metal layers. For example, the metal layers may have a three-layer structure of titanium/aluminum/titanium. The conductive layer of the multi-layer structure may include at least one metal layer and at least one transparent conductive layer.

The second insulating layer 230 may be interposed between the first conductive layer 220 and the second conductive layer 240. The second insulating layer 230 may include an inorganic film. The inorganic film may include at least one of aluminum oxide, titanium oxide, silicon oxide, silicon nitride, silicon oxynitride, zirconium oxide, or hafnium oxide.

Alternatively, the second insulating layer 230 may include an organic film. The organic film may include at least one of acrylate-based resin, methacrylate-based resin, polyisoprene, vinyl-based resin, epoxy-based resin, urethane-based resin, cellulose-based resin, siloxane-based resin, polyimide-based resin, polyimide-based resin, or perylene-based resin.

The anti-reflection layer ARL may be located on the sensor layer SSL. The anti-reflection layer ARL may include a division layer 310, a first color filter 321 (see FIG. 6A), a second color filter 322 (see FIG. 6A), a third color filter 323, and a planarization layer 330.

As long as a material absorbs light, the material constituting the division layer 310 is not particularly limited thereto. The division layer 310 may be a layer having a black color and, according to an embodiment, the division layer 310 may include a black coloring agent. The black coloring agent may include a black dye and a black pigment. The black coloring agent may include carbon black, a metal such as chromium, or an oxide thereof.

The division layer 310 may cover the second conductive layer 240 of the sensor layer SSL. The division layer 310 may prevent or reduce reflection of external light by the second conductive layer 240. The division layer 310 overlaps the second area DP-A2 (see FIG. 6A) and the third area DP-A3, and may not overlap the first area DP-A1 (see FIG. 6A). That is, as the division layer 310 is not located in the first area DP-A1, the transmittance of the first area DP-A1 may be further improved.

In the second area DP-A2, a first opening 310-OP1 may be defined in the division layer 310. The first opening 310-OP1 may overlap the anode AE2 of the second light emitting element LD2. The first color filter 321 may overlap the first area DP-A1, and the second color filter 322 may overlap the second area DP-A2. Each of the first color filter 321 and the second color filter 322 may overlap a corresponding anode among the anodes AE1 and AE2.

Because the division layer 310 does not overlap the first area DP-A1, the first color filter 321 may be spaced from the division layer 310. That is, the first color filter 321 may not contact the division layer 310. The second color filter 322 may cover the first opening 310-OP1. The planarization layer 330 may cover the division layer 310, the first color filter 321, and the second color filter 322.

As shown in FIG. 6B, in the third area DP-A3, a second opening 310-OP2 may be defined in the division layer 310. The second opening 310-OP2 may overlap the anode AE3 of the third light emitting element LD3. The third color filter 323 may overlap the third area DP-A3. The third color filter 323 may overlap the anode AE3 of the third light emitting element LD3. The third color filter 323 may cover the second opening 310-OP2. The third color filter 323 may contact the division layer 310.

The planarization layer 330 may cover the division layer 310 and the third color filter 323. The planarization layer 330 may include an organic material, and may provide a planarization surface on an upper surface of the planarization layer 330. According to an embodiment of the present disclosure, the planarization layer 330 may be omitted.

According to an embodiment of the present disclosure, the pixel defining layer PDL or the pixel circuit PC1, PC2, or PC3 corresponding to the light-shielding structure may not be positioned in the first area DP-A1, thereby increasing the distribution of the transmission area TA within the first area DP-A1 and providing the first area DP-A1 having relatively high light transmittance compared to surrounding areas.

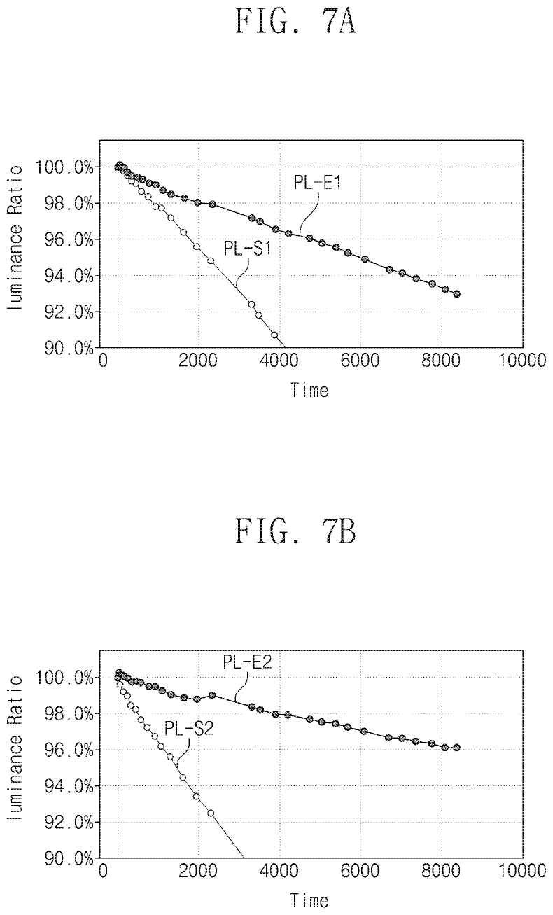

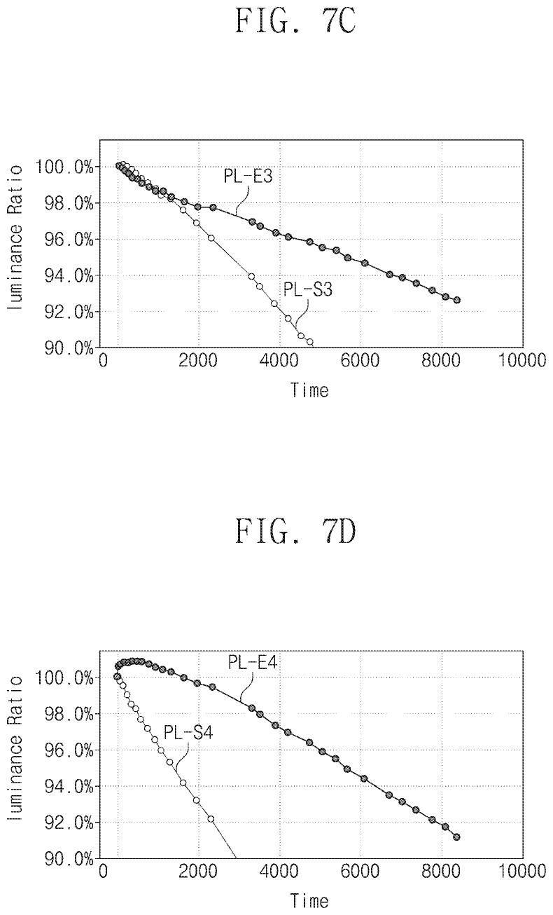

FIGS. 7A to 7D are graphs showing a lifetime of a light emitting element, according to an embodiment of the present disclosure. Graphs shown in FIGS. 7A to 7D show lifetimes of first light emitting elements and comparative examples, which emit light of different colors. FIGS. 7A to 7D show a luminance percentage graph according to a use time. The lifetime of an element may be identified through a luminance percentage decrease over time. The luminance percentage is obtained by expressing a ratio of current luminance to initial luminance as a percentage (%).

In detail, FIG. 7A shows a lifetime graph PL-E1 of the first light emitting element LD1 emitting white light and a lifetime graph PL-S1 of a first comparative example emitting the same white light. FIG. 7B shows a lifetime graph PL-E2 of the first light emitting element LD1 emitting red light and a lifetime graph PL-S2 of a second comparative example emitting the same red light. FIG. 7C shows a lifetime graph PL-E3 of the first light emitting element LD1 emitting green light and a lifetime graph PL-S3 of a third comparative example emitting the same green light. FIG. 7D shows a lifetime graph PL-E4 of the first light emitting element LD1 emitting blue light and a lifetime graph PL-S4 of a fourth comparative example emitting the same blue light. The first light emitting element LD1 may be a light emitting element having a structure in which two light emitting units are stacked. On the other hand, each of the first to fourth comparative examples may be a light emitting element having a single light emitting unit structure.

Referring to FIGS. 7A to 7D, all the first light emitting elements LD1 have graphs with a relatively gentle slope as compared to the comparative examples. That is, it may be seen that the first light emitting elements LD1 has a relatively high lifetime compared to the comparative examples. In addition, it may be seen that a structure including stacked light emitting units is capable of implementing a long lifetime higher than a structure including a single light emitting unit.

In the meantime, as in the above description, experimental data obtained by comparing lifetime opening rates per opening area size are shown in Table 1 below.

TABLE 1

| | Comparative examples | | Embodiments | |
|---|---|---|---|---|
| | Opening | Lifetime | Opening area | Lifetime |
| | area size | opening rate | size | opening rate |
| Classification | (μm²) | (%) | (μm²) | (%) |
| Red light | 223.7 | 14.56 | 68.37 | 4.45 |
| emitting | | | | |
| element | | | | |
| Green light | 111.83 | 14.56 | 55.15 | 7.18 |
| emitting | | | | |
| element | | | | |
| Blue light | 355.66 | 23.15 | 171.61 | 11.17 |
| emitting | | | | |
| element | | | | |

In Table 1, comparative examples may correspond to second to fourth comparative examples shown in FIGS. 7B to 7D, respectively. That is, the comparative example may be a light emitting element having a single light emitting unit structure. Embodiments may correspond to the first light emitting elements shown in FIGS. 7B to 7D, respectively. That is, the embodiments may include a light emitting element having a structure in which a plurality of light emitting units are stacked. The opening area size corresponds to the area size of an opening formed in the above-described pixel defining layer PDL (see FIG. 6A) or the pixel defining pattern PDP, and may substantially mean a light emitting area size. A lifetime opening rate may mean an opening rate required to have a reference lifetime. The lifetime opening rate of each of the comparative examples shown in Table 1 may correspond to the corresponding opening area size. That is, in a case of a comparative example emitting red, an opening area size of 223.7 μm² is required to have a lifetime (e.g., a set or predetermined lifetime) (hereafter referred to as a “reference lifetime”), which is a standard. This may correspond to an opening rate of 14.56%. In a case of the comparative example emitting green, an opening area size of about 111.83 μm² is required to have the reference lifetime. This may correspond to an opening rate of 14.56%. Likewise, in a case of the comparative example emitting blue, an opening area size of about 355.66 μm² is required to have the reference lifetime. This may correspond to an opening rate of 23.15%.

On the other hand, embodiments according to the present disclosure may have an opening lifetime rate of about 5% or less in a case of a red light emitting element, may have an opening lifetime rate of about 8% or less in a case of a green light emitting element, and may have a lifetime opening rate of about 12% or less in a case of a blue light emitting element. In detail, Table 1 shows embodiments in which the red light emitting element has an opening lifetime rate of about 4.45%, embodiments in which the green light emitting element has an opening lifetime rate of about 7.18%, and embodiments in which the blue light emitting element has a lifetime opening rate of about 11.17%. In other words, in a case of the red light emitting element, embodiments having a structure in which two light emitting units are stacked may have a lifetime opening rate reduced by about 70% as compared to the comparative example having a single light emitting unit structure. Likewise, it is understood that, in a case of the green light emitting element, embodiments having a structure in which two light emitting units are stacked may have a lifetime opening rate reduced by about 50% as compared to the comparative example having a single light emitting unit structure. It is understood that, in the case of a blue light emitting element, embodiments having a structure in which two light emitting units are stacked may have a lifetime opening rate reduced by about 42% compared to the comparative example having a single light emitting unit structure.

According to an embodiment of the present disclosure, it may have a high lifetime for the same opening area size compared to a structure including a single light emitting unit, by designing the first light emitting element LD1 in a structure in which a plurality of light emitting units are stacked. Accordingly, even when the opening area size of the first light emitting element LD1 is reduced, lifetimes of light emitting elements in the first area DP-A1 (see FIG. 6A) may be prevented from being reduced. Accordingly, according to an embodiment of the present disclosure, the emission area size within the first area DP-A1 may be reduced by designing the first light emitting element LD1 in a structure in which a plurality of light emitting units are stacked. Accordingly, the first area DP-A1 having improved light transmittance may be easily provided.

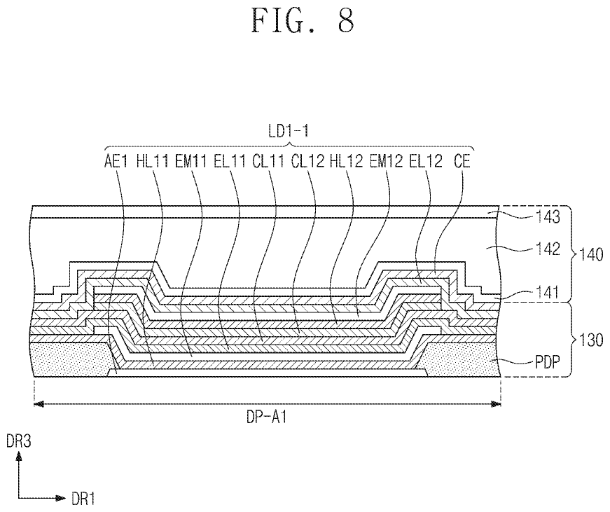

FIG. 8 is a cross-sectional view of a first light emitting element, according to an embodiment of the present disclosure. For ease of description and illustration, FIG. 8 shows portions of the light emitting element layer 130 and the encapsulation layer 140, which include a first light emitting element LD1-1. Hereinafter, a configuration the same as the configuration described with reference to FIGS. 1 to 7D is marked by the same reference numerals/symbols, and thus, additional description will be omitted to avoid redundancy.

The first light emitting element LD1-1 may further include a first hole transport layer HL11, a first electron transport layer EL11, an N-dopant layer CL11, a P-dopant layer CL12, a second hole transport layer HL12, and a second electron transport layer EL12. The first hole transport layer HL11 is interposed between the anode AE1 and the first light emitting layer EM11 to facilitate the movement of holes from the anode AE1 to the first light emitting layer EM11. The first electron transport layer EL11 facilitates the movement of electrons to the first light emitting layer EM11.

The N-dopant layer CL11 and the P-dopant layer CL12 constitute the charge generation layer CL1 (see FIG. 6A). For example, the N-dopant layer CL11 may include an alkali metal, an alkaline earth metal, a lanthanide-based metal, or a combination thereof. For example, the P-dopant layer CL12 may include a p-type dopant such as a quinone derivative or a metal oxide.

The second hole transport layer HL12 is interposed between the P-dopant layer CL12 and the second light emitting layer EM12 to facilitate the movement of holes to the second light emitting layer EM12. The second electron transport layer EL12 is interposed between the cathode CE and the second light emitting layer EM12 to facilitate the movement of electrons to the second light emitting layer EM12.

The anode AE1, the first hole transport layer HL11, the first light emitting layer EM11, the first electron transport layer EL11, and the N-dopant layer CL11 constitute one light emitting unit, and the P-dopant layer CL12, the second hole transport layer HL12, the second light emitting layer EM12, the second electron transport layer EL12, and the cathode CE constitute another light emitting unit. As described above, the first light emitting element LD1-1 according to an embodiment of the present disclosure is designed in a structure in which a plurality of light emitting units are stacked, and thus the lifetime may be improved even at the opening rate of a small area size. Accordingly, a ratio of the emission area size occupied within the first area DP-A1 may be reduced. Accordingly, a display panel including the first area DP-A1 having improved transmittance while a lifetime is not degraded may be easily provided.

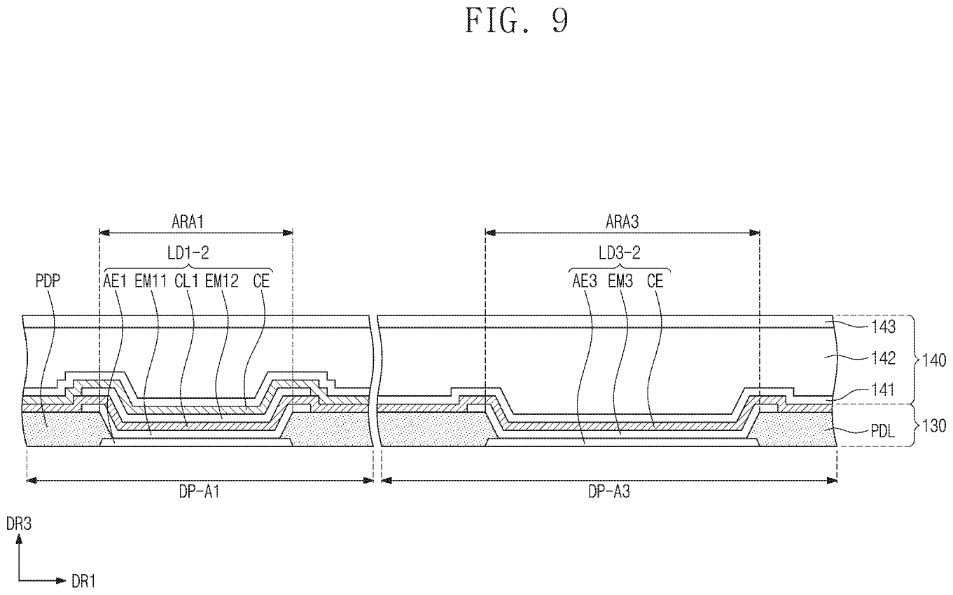

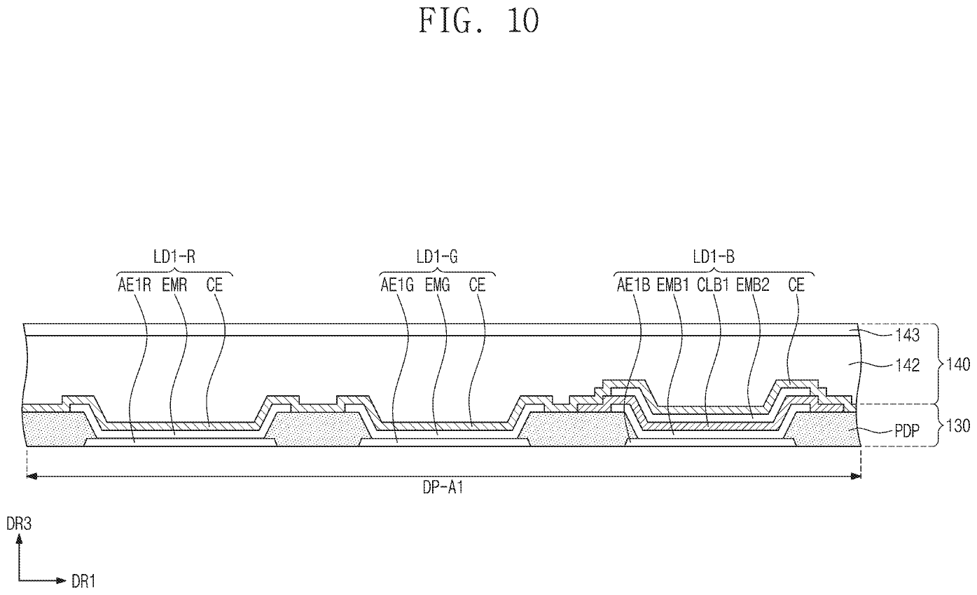

FIGS. 9 and 10 are cross-sectional views of a display panel, according to an embodiment. Hereinafter, aspects of an embodiment of the present disclosure will be described with reference to FIGS. 9 and 10. In the meantime, a configuration the same as the configuration described with reference to FIGS. 1 to 8 is marked by the same reference numerals/symbols, and thus, additional description will be omitted to avoid redundancy.

FIG. 9 shows a part of the first area DP-A1 and a part of the third area DP-A3 together. Referring to FIG. 9, a first light emitting element LD1-2 and a third light emitting element LD3-2 may have different structures from each other. The first light emitting element LD1-2 has a stacked structure of light emitting units including the first and second light emitting layers EM11 and EM12. On the other hand, the third light emitting element LD3-2 has a single light emitting unit structure including the anode AE3, a light emitting layer EM3, and the cathode CE. At this time, an emission area size ARA1 of the first light emitting element LD1-2 is illustrated to be smaller than an emission area size ARA3 of the third light emitting element LD3-2. According to an embodiment of the present disclosure, even when the first light emitting element LD1-2 has a smaller emission area size than the third light emitting element LD3-2 having a single light emitting unit structure, the first light emitting element LD1-2 may have a substantially equivalent lifetime, by having a structure in which light emitting units are stacked. Accordingly, the distribution of an emission area size in the first area DP-A1 may be reduced, and light transmittance of the first area DP-A1 may be improved.

FIG. 10 shows three first light emitting elements LD1-R, LD1-G, and LD1-B located in the first area DP-A1. The light emitting elements LD1-R, LD1-G, and LD1-B may be light emitting elements emitting red, green, and blue, respectively. Referring to FIG. 10, the first light emitting element LD1-R emitting red light may have a single light emitting unit structure including a single light emitting layer EMR; the first light emitting element LD1-G emitting green light may have a single light emitting unit structure including a single light emitting layer EMG; and, the first light emitting element LD1-B emitting blue light may have a structure in which light emitting units including a plurality of light emitting layers EMB1 and EMB2 are stacked. In detail, the first light emitting element LD1-R emitting red light may include an anode AE1R, the light emitting layer EMR, and the cathode CE; the first light emitting element LD1-G emitting green light may include an anode AE1G, the light emitting layer EMG, and the cathode CE; and, the first light emitting element LD1-B emitting blue light includes an anode AE1B, the first light emitting layer EMB1, a charge generation layer CLB1, the second light emitting layer EMB2, and the cathode CE.

According to an embodiment of the present disclosure, among the first light emitting elements LD1-R, LD1-G, and LD1-B, only the first light emitting element LD1-B emitting blue light with a relatively low lifetime may be selectively designed in a stacked light emitting unit structure, and the light emitting element LD1-R emitting red light with a relatively high lifetime or the light emitting element LD1-G emitting green light with a relatively high lifetime may be designed in a single light emitting unit structure. Compared to a light emitting element including only a single light emitting unit structure, a relatively complicated process and high costs may be required for a light emitting element in which a plurality of light emitting unit structures are stacked. According to an embodiment of the present disclosure, process costs may be reduced and process efficiency may be increased, by selectively designing only the blue light emitting element having a relatively low lifetime in a stacked structure.

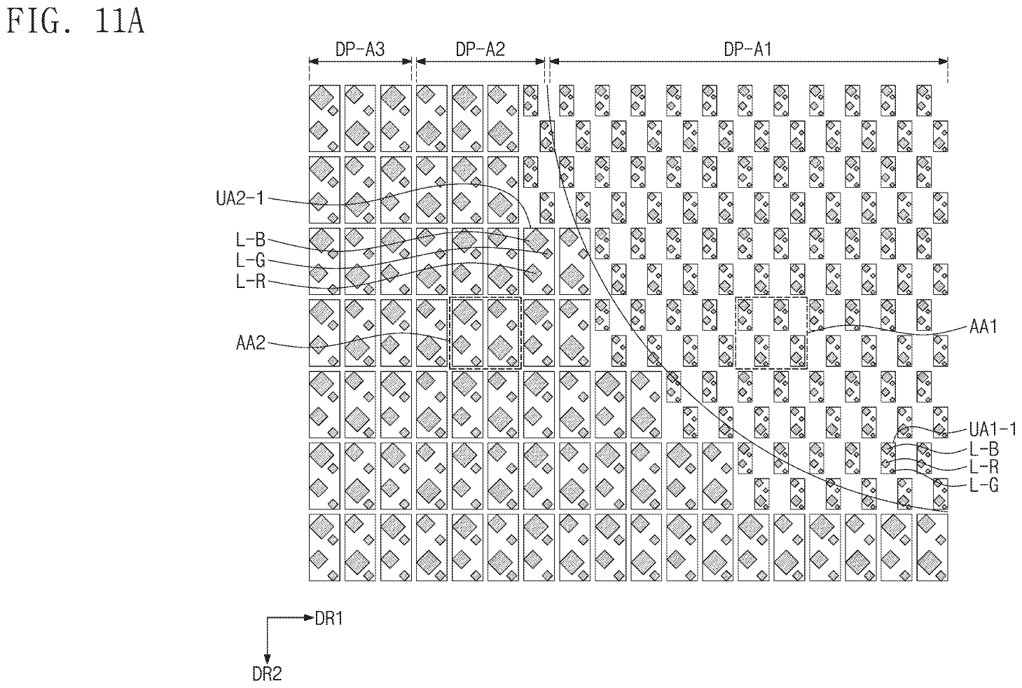

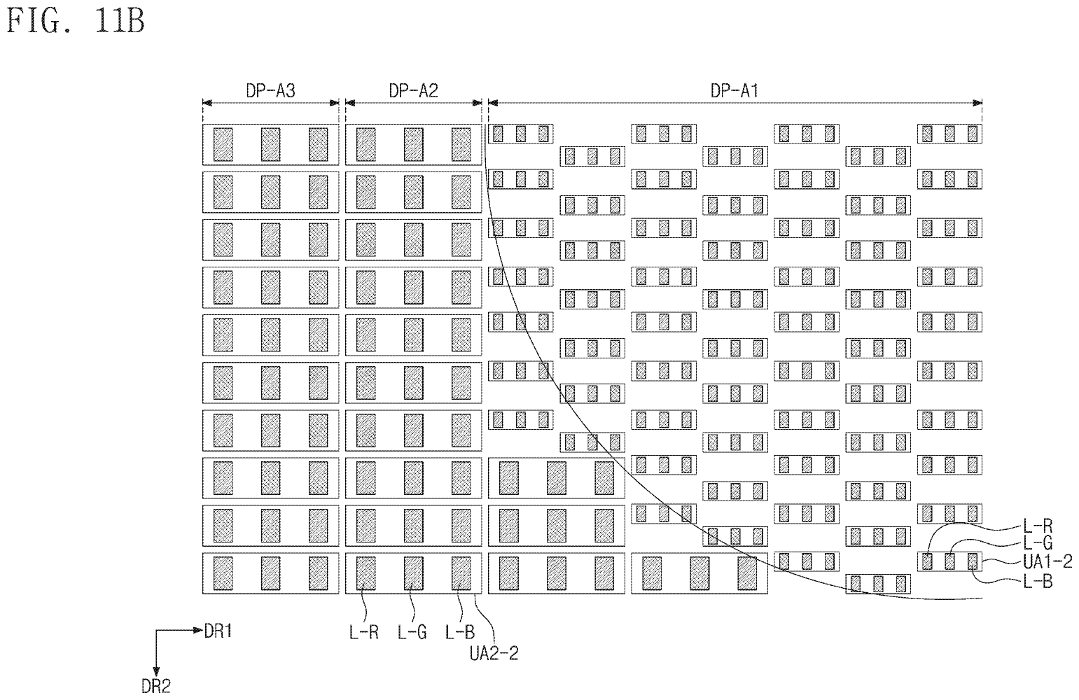

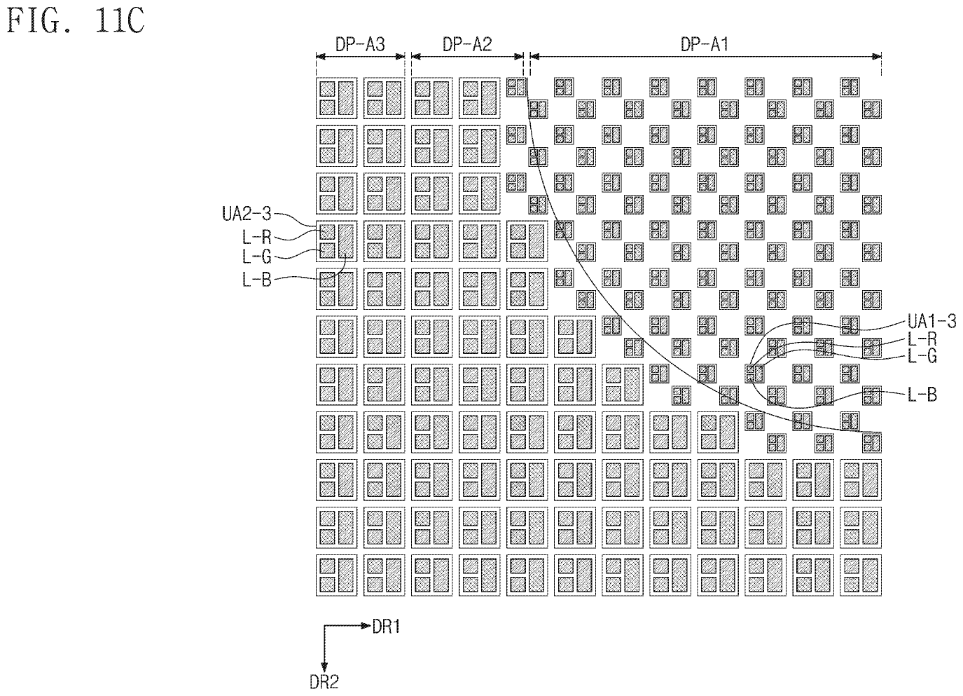

FIGS. 11A to 11C are plan views schematically illustrating a portion of a display panel, according to an embodiment of the present disclosure. Each of FIGS. 11A to 11C show emission areas of light emitting elements. Hereinafter, the present disclosure will be described with reference to FIGS. 11A to 11C. In the meantime, a configuration the same as the configuration described with reference to FIGS. 1 to 10 is marked by the same reference numerals/symbols, and thus, additional description will be omitted to avoid redundancy.

FIG. 11A shows emission areas L-R, L-G, and L-B of light emitting elements. The first emission area L-R is an emission area of a first color pixel; the second emission area L-G is an emission area of a second color pixel; and, the third emission area L-B is an emission area of a third color pixel.

The first area DP-A1 includes a plurality of first unit areas UA1-1. The first unit areas UA1-1 may be spaced from one another. Empty spaces between the first unit areas UA1-1 may correspond to the above-described transmission area TA (see FIG. 6A). That is, according to an embodiment, the first unit areas UA1-1 and the transmission areas TA may be alternately arranged.

The plurality of first unit areas UA1-1 have the same emission area arrangement as one another. Each of the plurality of first unit areas UA1-1 includes the first emission area L-R, the second emission area L-G, and the third emission area L-B. According to an embodiment, each of the plurality of first unit areas UA1-1 may include the one first emission area L-R, the two second emission areas L-G, and the one third emission area L-B. The first emission area L-R and the third emission area L-B may be arranged in a line in the second direction DR2, and the two second emission areas L-G may be arranged in a line in the second direction DR2. The arrangement order and arrangement shape of the first to third emission areas L-R, L-G, and L-B in the first unit area UA1-1 may be variously changed. For example, the first emission area L-R and the third emission area L-B may be arranged in a line in the first direction DR1, and the two second emission areas L-G may be arranged in a line in the first direction DR1. For another example, the two second emission areas L-G may be arranged to face each other in a diagonal direction between the first direction DR1 and the second direction DR2. The first emission area L-R and the third emission area L-B may be arranged to face each other in the diagonal direction.

Meanwhile, one of the two second emission areas L-G may be defined as a fourth emission area distinguished from the second emission area L-G. For example, the second emission area L-G and the fourth emission area may have different shapes from each other on a plane. The number and type of emission areas included in the plurality of first unit areas UA1-1 are not particularly limited thereto.

According to an embodiment, the first emission area L-R may be a first color emission area and may generate red light. Each of the two second emission areas L-G may be a second color emission area and may generate green light. The third emission area L-B may be a third color emission area and may generate blue light. As described above, red light, green light, and blue light may be changed into three pieces of other main color light.

Each of the second area DP-A2 and the third area DP-A3 includes a plurality of second unit areas UA2-1. According to an embodiment, the second area DP-A2 and the third area DP-A3 may be designed in the same shape as each other. However, this is illustrated by way of example. The second area DP-A2 and the third area DP-A3 may be designed in different shapes. For example, the third area DP-A3 may include third unit areas different from those of the second unit areas UA2-1.

The plurality of second unit areas UA2-1 have the same emission area arrangement as one another. Each of the plurality of second unit areas UA2-1 includes the first emission area L-R, the second emission area L-G, and the third emission area L-B. According to an embodiment, each of the plurality of second unit areas UA2-1 may have the same arrangement of emission areas as each of the plurality of first unit areas UA1-1.

The second unit area UA2-1 may have an area size larger than the first unit area UA1-1. That is, the first emission area L-R in the second unit area UA2-1 may have a larger area size than the first emission area L-R in the first unit area UA1-1. The second emission area L-G in the second unit area UA2-1 may have a larger area size than the second emission area L-G in the first unit area UA1-1. The third emission area L-B in the second unit area UA2-1 may have a larger area size than the third emission area L-B in the first unit area UA1-1. When emission area sizes of light emitting elements corresponding to each other are different from each other and the same driving voltage is applied to the corresponding light emitting elements, a luminance ratio of the light emitting elements corresponding to each other depends on an emission area size ratio.

Because the second unit area UA2-1 has an area size larger than the first unit area UA1-1, the number of emission areas per unit area size in the first area DP-A1 is greater than that in the second area DP-A2. For example, on the basis of a first unit area AA1 and a second unit area AA2 having the same unit area size as each other, the number of emission areas arranged in the first unit area AA1 may be sixteen, and the number of emission areas arranged in the second unit area AA2 may be eight.

Because the first area DP-A1 has the number of emission areas per unit area size more than the second area DP-A2, the first area DP-A1 may have higher luminance per unit area size than the second area DP-A2 when the same emission area size and the same driving conditions are satisfied. The same emission area size means that an area size of a corresponding emission area in the first unit area UA1-1 is the same as an area size of a corresponding emission area in the second unit area UA2-1. The same driving condition means that the same driving voltage is applied to light emitting elements corresponding to each other.

According to an embodiment of the present disclosure, each of the first, second, and third emission areas L-R, L-G, and L-B in the first area DP-A1 has an area size smaller than the corresponding emission area among the first, second, and third emission areas L-R, L-G, and L-B in the second area DP-A2 or the third area DP-A3. When emission area sizes of light emitting elements corresponding to each other are different from each other and the same driving voltage is applied to the corresponding light emitting elements, a luminance ratio of the light emitting elements corresponding to each other depends on an emission area size ratio.

According to an embodiment of the present disclosure, the first light emitting element LD1 may have a lifetime higher than an expected lifetime in an emission area composed of a single light emitting unit by designing the first light emitting element LD1 (see FIG. 6A) in a structure in which a plurality of light emitting units are stacked. Accordingly, area sizes of the emission areas L-R, L-G, and L-B that occupy the first unit area UA1-1 may be reduced, and thus the initial luminance of an emission area of the first area DP-A1 may increase as the luminance per unit area size of the first area DP-A1 increases. However, as compared to a case where an emission area is designed in a structure having a single light emitting layer, issues on lifetime degradation may be resolved. Accordingly, the first area DP-A1 may have the same luminance as the surrounding areas DP-A2 and DP-A3 while having improved light transmittance, and the first area DP-A1 in which the issues on lifetime degradation are resolved may be provided.

Referring to FIG. 11B, first unit areas UA1-2 and second unit areas UA2-2 may be arranged in a matrix shape in the first direction DR1 and the second direction DR2. The first unit area UA1-2 may include three emission areas L-R, L-G, and L-B arranged in a line in the first direction DR1. The second unit area UA2-2 may include the emission areas L-R, L-G, and L-B having the same arrangement as the first unit area UA1-2. The area size of the first unit area UA1-2 may be smaller than the area size of the second unit area UA2-2. The area sizes of the emission areas L-R, L-G, and L-B of the first unit area UA1-2 may be smaller than those of the emission areas L-R, L-G, and L-B of the second unit area UA2-2, respectively. Accordingly, the area size occupied by an emission area in the first area DP-A1 may be reduced and light transmittance may be improved.

Referring to FIG. 11C, first unit areas UA1-3 and second unit areas UA2-3 may be arranged in a matrix shape in the first direction DR1 and the second direction DR2. The first unit area UA1-3 may include the first emission area L-R located in the second direction DR2, the second emission area L-G located in the second direction DR2, and the third emission area L-B facing the first emission area L-R and the second emission area L-G in the first direction DR1. The third emission area L-B may have an area size larger than the sum of an area size of the first emission area L-R and an area size of the second emission area L-G. The second unit area UA2-3 may include the emission areas L-R, L-G, and L-B having the same arrangement as the first unit area UA1-3.

The area size of the first unit area UA1-3 may be smaller than the area size of the second unit area UA2-3. The area sizes of the emission areas L-R, L-G, and L-B of the first unit area UA1-3 may be smaller than those of the emission areas L-R, L-G, and L-B of the second unit area UA2-3, respectively. Accordingly, the area size occupied by an emission area in the first area DP-A1 may be reduced and light transmittance may be improved.

According to an embodiment of the present disclosure, the emission areas L-R, L-G, and L-B constituting each of the first unit area UA1-1, UA1-2, and UA1-3 may be designed as the first light emitting element LD1 (see FIG. 6A) including a plurality of light emitting units, thereby preventing an expected lifetime from being reduced as the area sizes of the emission areas L-R, L-G, and L-B are reduced.

Accordingly, a display panel including the first area DP-A1 having relatively improved light transmittance and a sufficient expected lifetime may be provided. Although aspects of an embodiment of the present disclosure have been described for illustrative purposes, those skilled in the art will appreciate that various modifications, and substitutions are possible, without departing from the scope and spirit of embodiments according to the present disclosure as disclosed in the accompanying claims, and their equivalents. Accordingly, the technical scope of the present disclosure is not limited to the detailed description of this specification, but should be defined by the claims, and their equivalents.

According to an embodiment of the present disclosure, an area size of a light emitting element in an area where an electronic module is arranged may be reduced. Accordingly, light transmittance of the area where the electronic module is arranged may be relatively improved.

While the present disclosure has been described with reference to embodiments thereof, it will be apparent to those of ordinary skill in the art that various changes and modifications may be made thereto without departing from the spirit and scope of the present disclosure as set forth in the following claims, and their equivalents.

What is claimed is:

1. A display apparatus comprising:
a base substrate divided into a first area and a second area adjacent to the first area;
a pixel defining layer on the base substrate and having a first opening in the first area with a first area size, and a second opening in the second area with a second area size greater than the first area size;
a first light emitting unit having an emission area size corresponding to the first area size and configured to emit a first color light;
a second light emitting unit having an emission area size corresponding to the second area size and configured to emit the first color light;
a first pixel circuit in the second area and connected to the first light emitting unit;
a second pixel circuit in the second area and connected to the second light emitting unit; and
an electronic module in the first area and overlapping the first opening,
wherein the first light emitting unit includes a first charge generation layer, and
wherein an opening rate of the first light emitting unit is smaller than an opening rate of the second light emitting unit.

2. The display apparatus of claim 1, wherein the first light emitting unit has an opening rate of 12% or less.

3. The display apparatus of claim 1, wherein the first color light is red or blue.

4. The display apparatus of claim 3, wherein the first light emitting unit has an opening rate of 5% or less.

5. The display apparatus of claim 1, wherein the first color light is green.

6. The display apparatus of claim 5, wherein the first light emitting unit has an opening rate of 8% or less.

7. The display apparatus of claim 1, wherein the first light emitting unit includes a plurality of light emitting layers, and
wherein the second light emitting unit includes a single light emitting layer.

8. The display apparatus of claim 1, further comprising:
a third light emitting unit in the first area and configured to emit a second color light different from the first color light,
wherein the first light emitting unit includes a plurality of light emitting layers, and
wherein the third light emitting unit includes a single light emitting layer.

9. The display apparatus of claim 1, wherein the first color light is white.

10. The display apparatus of claim 1, wherein the electronic module includes a camera, an ultrasonic sensor, or an optical sensor.

11. The display apparatus of claim 1, wherein the first area size is in a range of ½ to ⅓ of the second area size.

12. A display apparatus comprising:
a base substrate divided into a first area and a second area adjacent to the first area;
a first light emitting unit in the first area and including a first anode having a first area size, a first light emitting layer, a second light emitting layer, and a first cathode;
a second light emitting unit in the second area and including a second anode having a second area size greater than the first area size, a third light emitting layer, and a second cathode;
a third light emitting unit in the first area and including a third anode, a fourth light emitting layer, and a third cathode; and
an electronic module in the first area and overlapping a first opening exposing at least part of the first anode,
wherein the first light emitting unit and the second light emitting unit are configured to emit a first color light,
wherein the third light emitting unit is configured to emit a second color light different from the first color light, and
wherein the first area size is ½ or less of the second area size.

13. The display apparatus of claim 12, wherein the first light emitting unit has an opening rate of 12% or less.

14. The display apparatus of claim 12, wherein the first color light is blue, and
wherein the third light emitting unit includes a single light emitting layer.

15. The display apparatus of claim 14, wherein the third light emitting unit further includes a fourth light emitting layer.

16. The display apparatus of claim 15, wherein the second color light is red, and
wherein the third light emitting unit has an opening rate of 5% or less.

17. The display apparatus of claim 15, wherein the second color light is green, and
wherein the third light emitting unit has an opening rate of 8% or less.

18. The display apparatus of claim 12, wherein the second light emitting unit includes a single light emitting layer.

19. The display apparatus of claim 12, further comprising:
a second opening exposing at least part of the second anode; and
a pixel defining layer exposing at least part of the third anode,
wherein a fourth opening in the first area and spaced from the first opening and the second opening is defined on the pixel defining layer, and
wherein a light emitting layer is not in the fourth opening.

20. The display apparatus of claim 19, wherein a plurality of first openings included in the first opening, a plurality of second openings included in the second opening, and a plurality of fourth openings included in the fourth opening are provided in the first area, and
wherein the plurality of first openings, the plurality of second openings, and the plurality of fourth openings are alternately arranged.
